(19) United States
(12) Patent Application Publication
(10) Pub. No.: US 2003/0168627 A1
(43) Pub. Date: Sep. 11, 2003

(54) Slurry and method for chemical mechanical polishing of metal structures including refractory metal based barrier layers

(76) Inventors: Rajiv K. Singh, Gainesville, FL (US); Seung-Mahn Lee, Gainesville, FL (US)

Correspondence Address: Gregory A. Nelson, Esq., Akerman, Senterfitt & Eidson, P.A., 222 Lakeview Avenue, Suite 400, P.O. Box 3188, West Palm Beach, FL, 33402-3188, US

(21) Appl. No.: 10/082,010

(22) Filed: Feb. 22, 2002

(51) Int. Cl. C09K 13/00; H01L 21/4763

(52) U.S. Cl. 252/79.1

(57) ABSTRACT

A slurry for chemical mechanical polishing (CMP) of a refractory metal based barrier film includes a plurality of composite particles and at least one selective adsorption additive, such as a surfactant or a polymer. The composite particles have an inorganic core surrounded by the selective adsorption additive. The refractory metal based barrier film does not substantially adsorb the selective adsorption additive surfactant, while other exposed films substantially adsorb the surfactant. A method for chemical mechanical polishing (CMP) a refractory metal based barrier film includes the steps of providing a slurry including a plurality of composite particles and at least one selective adsorption additive. The invention can be used for a single step CMP process for polishing a structure including a gate or interconnect metal layer, a refractory metal based barrier film and a dielectric film, first removing gate or interconnect overburden metal and then removing the overburden regions of the refractory metal based barrier film in a single polishing step.

### STATEMENT REGARDING FEDERALLY SPONSORED RESEARCH OR DEVELOPMENT

Not applicable

### FIELD OF THE INVENTION

This invention relates to a slurry and method for chemical-mechanical polishing of structures including refractory metal based barrier layers.

### BACKGROUND

Reductions in semiconductor device dimensions provide higher densities and improved performance for integrated circuits. In many integrated electronic devices, millions of discrete elements, such as transistors, resistors and capacitors, are interconnected. Due to an increase in device density provided by scaling of semiconductor processes to improve circuit performance, it is no longer generally possible to utilize a single metal interconnect level. Single level interconnects result in significant parasitic resistance which can adversely affect device performance, particularly the dynamic performance of the integrated circuit.

Copper has become an increasingly popular choice for interconnect metal and has begun replacing aluminum in certain applications. Copper is much more conductive than aluminum, allowing finer wires having lower resistive losses. Copper is also significantly less vulnerable to electromigration than aluminum and less likely to fracture under stress. Electromigration is the drift of metal atoms when a conductor carries high current densities, and can create reliability problems through generation of voids and other defects.

Although copper provides advantages over aluminum, it has at least one major disadvantage. Copper is poisonous to silicon since it readily diffuses into silicon and causes deep-level defects. Therefore, copper must be isolated from silicon, usually through the use of a suitable refractory metal based barrier layer.

Multilevel metallization structures have been developed which include an interconnection structure having several levels of metallization separated by thin insulating layers. Metal plugs are used to connect the different metal levels to one another. Presently, aluminum alloys (e.g. Al/Si/Cu) are still commonly used for the metal interconnect, while tungsten is generally used for plug structures as the material of choice for interconnecting two levels of metals. Aluminum and its alloys are generally dry etched, such as by reactive ion etching and plasma etching. However, dry etching of copper is not currently feasible. Accordingly, when copper and its alloys are used instead of conventional aluminum or aluminum alloys as an interconnection material, alternative techniques are employed to define the copper lines.

For example, a damascene process together with chemical-mechanical polishing (CPM) can be used to define copper lines. In a damascene process, trenches are etched in a dielectric material, such as silicon dioxide (SiO₂). A barrier material is then deposited, generally by sputtering. Copper is then deposited typically using electrodeposition techniques (e.g. electroplating) to fill the barrier lined trenches. The overburden regions of the copper film are then removed by CMP to define the copper lines.

CMP combines both chemical action and mechanical forces and is commonly used to remove metal overlayers in damascene processes, remove excess oxide in shallow trench isolation steps and to reduce topography across a dielectric region. Components required for CMP include a chemically reactive liquid medium and a polishing surface to provide the mechanical control required to achieve planarity.

Either the liquid or the polishing surface may contain nano-size inorganic particles to enhance the reactive and mechanical activity of the process. Typically, a chemically modified thin layer on the wafer surface is formed, such as a metal oxide, and then abrasives are used to remove the chemically modified layer from the surface. Once the surface layer is removed, a thin passive film is reformed rapidly on the surface and controls the removal process. CMP is the only technique currently known for producing die level flatness required for sub 0.5 μm devices and is considered a requirement for the production of sub 0.2 μm device structures and state-of-the-art metal interconnect schemes.

Metals can also be used to form the gate electrode of certain devices. In this case, the metal gate can provide the electrical pathway for switching the device. In the case of a MOS transistor, the gate dielectric is typically silicon dioxide while the typical gate electrodes presently used are generally formed from heavily doped polysilicon. Alternative gate dielectrics having improved properties may soon replace SiO₂. For example, novel high dielectric constant materials such as yttria stabilized zirconia (YSZ), hafnia, lanthanum oxide, and certain silicates are expected to find increasing use for future high performance applications.

To use novel high dielectric constant gate dielectrics more efficiently, gate electrode materials such as Ta, Cu and Pt may also become used. Other possible metallic materials may include Os, Ru, TiN, TaSiN, IrO₂, RuO₂ and other conducting oxides such as tin oxide (SnO₂), indium tin oxide, and related mixtures and alloys. Copper may be deposited on top of these material systems. Besides the use of copper in interconnects for CMOS devices and gate structures in high dielectric constant materials, there may be number of emerging applications such as ferroelectric random access memory devices (FeRAM), tunneling magnetoresistance (TMR) or giant magnetoresistance (GMR) devices where copper is deposited on a metal or a dielectric structure. In a FeRAM, copper may be used as the interconnecting metal or as sandwich metal layer on a gate electrode system. In a TMR or a GMR device, copper can be used as a back terminal, front end terminal or an electrode on a multilayer magnetic/non-magnetic structure. To create these specific structures it is also essential to remove copper selectively from the surface, but not to remove the underlying dielectric or metallic material.

The dielectric used in multiple level interconnect structures is typically silicon dioxide or doped silicon dioxide. With the rapid progression in device speeds to 1 GHz or more, circuit performance becomes increasingly limited by the interconnect system. Thus, it has become increasingly important to use dielectric materials which have a dielectric constant (K) below that of silicon dioxide, silicon dioxide having a K of approximately 4. Dielectrics which have a dielectric constant less than 4 are typically referred to as “low K” materials. Examples of low K materials which may find increasing use as device speeds increase include doped silicon oxide, such as BLACK DIAMOND®, produced by the Applied Materials Corporation, Santa Clara, Calif.

Introducing low K dielectric materials as inter-metal dielectric can produces a major improvement to device performance by lowering the line-to-line capacitance which increases device speed by reducing interconnect RC delay. These materials also can reduce cross-talk noise in the interconnect and can alleviate power dissipation issues.

FIG. 1 shows a schematic view of the steps in a copper damascene CMP process. A low dielectric constant material disposed on a silicon wafer is patterned by suitable etching to form a plurality of trenches 110 as shown in FIG. 1(a). A diffusion barrier layer 120, such as Ti, Ta, WN, TaSiN or TaN, is then applied to cover the wafer surface, including the trenches 110 as shown in FIG. 1(b). A copper or copper alloy layer 130 is then deposited, by a method such as electroplating. (FIG. 1(c)). The copper or copper alloy layer is isolated from the remainder of the circuit by the barrier layer 120. Copper (or metal in general) disposed over dielectric plateaus is commonly referred to as overburden metal 131.

A CMP process can then be used to define the copper layer through an essentially planar removal process. The CMP process proceeds to remove the copper layer sufficient to remove the overburden portion 131 to expose the barrier layer in the overburden regions to produce the structure 140 shown in FIG. 1(d). A second CMP step, generally using a different slurry as compared to the copper CMP process, is then used to polish the barrier layer and produce the completed structure 150 which is shown in FIG. 1(e). This process can be repeated to produce multiple copper or other conductor levels to form a plurality of interconnect or other levels.

FIG. 2 shows a schematic view of a CMOS transistor 200 having a metal gate formed from a damascene/CMP process. Transistor 200 is shown following CMP polishing of a gate metal, such as Cu, Pt, Os, Ir, IrO₂, Ru, RuO₂ or Ta, using a damascene/CMP process analogous to the copper interconnect process discussed above. Transistor 200 includes silicon substrate 201, the transistor having a source 202 and a drain 203. The source 202 and drain 203 have lightly doped extensions made possible in previous processing by spacer 204 and 205. A gate aperture is provided in field oxide 208 to reach the silicon substrate 201. A thin gate oxide 218 is disposed on top of silicon substrate 201. Barrier layer 212 is then disposed over gate oxide 218 and on the sidewalls of the gate aperture provided by spacers 204 and 205. Gate metal 215 fills the gate aperture volume and is disposed over barrier layer 212.

Whether an interconnect or a gate electrode is formed using CMP, it is important to stop the CMP process soon after the metal layer is fully removed to minimize removal of underlying layers. Since the metal thickness and polishing rates can be non-uniform across the wafer area, it is also helpful for the CMP process to provide a low polishing rate of the underlying layers below the metal, relative to the metal removal rate.

A diagram of a conventional CMP polisher 300 is shown in FIG. 3. The CMP polisher includes a polishing pad 310 disposed on a platen 320 which rotates. A wafer 330 is pressed into direct contact with the polishing pad by a force exerting structure 350. A slurry solution is provided by a slurry feed 340 to wet the polishing pad 310 which chemically and physically interacts with the surface of the wafer 330.

Conventional slurries used for the CMP include a solid abrasive and an oxidizing substance. Typically, CMP polishing slurries contain a plurality of alumina or silica particles suspended in an oxidizing aqueous medium. In FIG. 3, the polishing pad 310 is attached to the top of the rotating platen 320, while the wafer 330 is brought in contact with the pad 310 from the top. The wafer 330 can either be rotated or kept stationary. The wafer 330 can be moved in a circular, elliptical or in a linear manner with respect to the polishing pad 310. The pressure on the wafer 330 is generally varied from 0.1 psi to 10 psi, and the rotation speed of the platen 320 is generally varied from 5 rpm to 300 rpm.

The polymeric pad 310 supplies the mechanical component of the polishing process. The harder the polymeric pad 310, the higher the shear stress on the surface of the wafer. However the contact area on the surface will decrease when a harder pad is employed in the process. Typical pads which are commonly used include IC1000 CMP pads manufactured by Rodel Corporation, located in Newark, Del.

The diameter of the platen wheels 320 can vary from 10 inches to 45 inches, while the size of the wafer can vary from 1 inches to 12 inches in diameter. To maintain a fixed linear velocity, either the angular velocity can be increased or the radius of the wafer from the center can be increased. It is generally important to generate a linear movement of the pad across the wafer.

When polishing a copper/tantalum/insulator based multi-level structure, copper and the tantalum are generally polished by different slurries in separate CMP steps because of significant differences in the mechanical, chemical and electrochemical properties between copper and tantalum. Copper is a very soft and chemically reactive material, whereas common refractory metal based barrier films, such as WN, TiN, Ta, Ta containing alloys and Ta compounds such as Ta₂O₅, TaN, as well as Hf and Ru are chemically passive and mechanically hard materials. Thus, the removal rates of copper and refractory metal based films are quite different for a given slurry composition. Accordingly, two-step CMP processes are generally used when circuits include copper and refractory metal based films. The first step polishes the copper surface, while a second step polishes the refractory metal based film.

Slurries designed to polish tantalum containing layers contain abrasives such as alumina, titania and silica, oxidizing agents such as hydrogen peroxide, potassium iodate or potassium ferricynide, and other optional additives. Aggressive polishing methodologies are generally used to remove the chemically passive and mechanically hard tantalum containing layers. As a result, the generally soft surface layers underlying the tantalum layer, such as SiO₂ or a low K material, can be damaged. For example, scratches can result which can degrade circuit performance and yield and may also degrade reliability of the integrated circuits. Moreover, the use of conventional refractory metal based slurry chemistries are known to result in several other problems, such as surface defects, dishing and erosion problems, and film peeling.

The surface of the refractory metal based film before the CMP process to polish the same generally has numerous surface non-homogenities, that are necessary to remove during polishing. Some important non-homogenities include residual copper patches and dishing and erosion in the copper regions of the exposed surface. Residual copper can be in form of small patches on top of the refractory metal based layer which were not removed during the copper CMP step. Residual copper may either be deliberately left during the copper polishing step or be the result of a non-uniform copper polishing process. For example, U.S. Pat. No. 5,985,748 to Watts, et. al. has suggested that the entire copper layer that is disposed on the tantalum containing barrier layer should not be removed during the copper CMP step. Thus, this process leads to a surface having patches of copper disposed on the tantalum containing layer.

The polishing of a refractory metal based surface which has residual copper poses more polishing challenges. If there are copper patches on the surface, the slurry is preferably able to polish copper at a rate comparable to that of the refractory metal based film. Kaufmann et al. in U.S. Pat. Nos. 6,063,306, 5,954,997 and 6,126,853 has suggested that the slurry for tantalum polishing should have a copper to tantalum polishing ratio between 2:1 and most preferably less than about 1:5. Having high polishing rates for copper compared to tantalum is not desirable because a surface morphology defects, such as dishing and erosion, depend on the ratio of the polishing rate of copper to tantalum. With high copper polishing rates, the dishing and erosion of the surface can increase significantly. Even relative low polishing rates of copper not desirable during tantalum polishing because the copper patches will not be removed.

Refractory metal based film polishing can result in dishing and erosion effects. Dishing results in the surface of the central part the metal interconnection being inlaid in a groove formed on the insulating film due to excessively polishing of the central part compared to the periphery. Erosion occurs when the insulating surface around the interconnection is polished. In erosion, both the metal and the insulating areas are depressed, whereas in dishing, the metal lines are depressed compared to refractory metal based film or the underlying insulating film.

Both dishing and erosion defects can already be present in the incoming wafers provided for refractory metal based film polishing. These defects generally result because the slurry used for copper polishing has a higher polishing rate of copper than compared to refractory metal based films, such as tantalum.

For example, the copper to tantalum polishing ratio can vary from 2:1 to as high as 45:1. The high selectivity of copper compared to tantalum or other barrier layer is necessary to stop the polishing process once the copper layer is removed. However, this can lead to substantial dishing of the surface. By using a slurry which has higher polishing rates for copper compared to tantalum, the dishing resulting from copper polishing can increase further.

To reduce the dishing and erosion introduced during refractory metal based film polishing, a slurry which has a lower polishing rate for copper than the refractory metal based film can be used. However, such a slurry has not been used because the refractory metal based films are mechanically hard and chemically passive and are necessarily removed slower than copper when CMP is used.

Refractory metal based film polishing can also result in the loss of the dielectric materials during the polishing process. The underlying dielectric materials are typically doped or undoped silicon dioxide or other low dielectric constant material such as carbon doped silica or certain polymeric materials. After polishing the refractory metal based film, the underlying dielectric layer becomes exposed. The slurry abrasives, such as silica or alumina, are typically hard and abrasive. These abrasives can also cause significant dielectric erosion and surface defects upon the underlying substrate.

The dielectric loss typically increases as the concentration of particles increase in the slurry, and increases for increasingly alkaline pH (pH>7 to 12). High dielectric erosion can cause surface non-planarity and loss of global planarization. To reduce the dielectric erosion, Watts has suggested using slurries that do not contain particles or only a low concentration of particles. Watts discloses use of 0.5 wt. % alumina particles in a slurry to polish the tantalum. Reduced particles can be expected to reduce the dielectric loss. However, reduced abrasive particle concentrations are also expected to substantially reduce the tantalum polishing rate.

Refractory metal based film polishing can also result in the introduction of surface defectivity on the final surface. The final surface generally consists of thin copper lines and contact hole plugs within a dielectric matrix. The dielectric is typically doped or undoped silicon dioxide, or possibly a new low-K dielectric material. The surface defectivity is characterized by scratches on the surface of copper and the insulator, surface roughness due to etching effects, and the presence of particles which can become attached to the surface. As most refractory metal based film slurries contain hard abrasives such as alumina or silica, these particles tend to scratch the surface of the dielectric and copper. To reduce the surface defectivity, the amount of hard abrasives can be reduced, but this problem still persists.

Refractory metal based film polishing can also result in film peeling of underlying layers. The underlying dielectric film is typically soft and may have poor adhesion to its underlying layer which can produce a tendency to peel. With the advent of new low dielectric constant thin films generally being softer than silicon dioxide, film peeling is expected to worsen. Standard slurries, which use hard abrasives such as silica and alumina, can damage, peel and delaminate the dielectric layer quite easily. Besides peeling and delamination of the surface, the hard abrasives can cause scratches, which can also reduce the yield and reliability of devices. To reduce the possibility of peeling, slurries can use softer particles, such as polymers. However, polymer particles are not expected to be effective for removing mechanically hard refractory metal based films, such as tantalum. Thus, the soft particle approach is not practical for polishing refractory metal based films.

Conventional refractory metal based film slurries can also cause destabilization of the slurry abrasives leading to agglomeration. Agglomeration can provide several unwanted effects in the CMP process including the formation of a large number of surface defects, wide variation in the CMP polishing rates and lack of process repeatability.

Thus, several problems need to be resolved for optimum polishing of refractory metal based films for semiconductor applications. Selectivity of tantalum to copper and dielectric layers is preferably high to limit dishing and erosion, while abrasive particle contact with layers other than the refractory metal based film is preferably avoided.

If CMP process selectivity could be significantly improved, a one step metal/barrier layer (e.g. Cu/Ta) polishing process could be developed. Such a process could replace the current two step process used to first polish the metal and then in a second step polish the barrier layer. A single step metal/barrier process could reduce cycle time, increase yields and result in significant cost savings.

### SUMMARY OF THE INVENTION

A slurry for chemical mechanical polishing (CMP) of a refractory metal based film includes a plurality of composite particles and at least one selective adsorption additive, the composite particles including an inorganic core surrounded by a shell provided by the selective adsorption additive. The selective absorption additive may comprise one or more surfactants or polymers. The surfactant or polymeric additive is not substantially adsorbed by the refractory metal based film, whereas other films, such as SiO₂, or a low K dielectric film substantially adsorb the selective adsorption additive.

As used herein, “substantial adsorption” relative to a given layer is defined as a degree of adsorption which results in a CMP polishing rate (for a given slurry and CMP polishing conditions) with the selective adsorption additive which is less than or equal to 1/3 of the CMP layer polishing rate when the slurry does not include the selective adsorption additive. On the other hand, “non-substantial adsorption” relative to a given film is defined as a degree of adsorption corresponding to a CMP polishing rate (for a given slurry and CMP polishing conditions) with the selective adsorption additive being more than 1/3 of the layer polishing rate when the slurry does not include the selective adsorption additive.

As both the particles and the dielectric film surface substantially adsorb the selective absorption additive, the CMP polish rate of the dielectric is substantially reduced in presence of the additive. On the other hand, the polishing rate of the non-substantially absorbed refractory metal based film or the embedded interconnect metal such as copper (or silver) is higher than the polishing rate of the substantially adsorbent dielectric film.

The term “chemically equivalent” as used herein, refers to materials which share the same chemical compositions, but which may or may not share the same physical structure. For example, the compound silicon dioxide (SiO₂) exists in amorphous form, such as the layers commonly grown or deposited during integrated circuit processing. Silicon dioxide (SiO₂) also exists in crystalline form and is commonly referred to as quartz or silica in this form. Other materials with chemical equivalence to silicon dioxide include Low K dielectrics including silica doped glasses such as fluorine silica glass (FSG), BLACK DIAMOND®, CORAL® and nano-porous silica.

The inorganic cores can be silica, alumina or zirconia particles. The inorganic cores can be composite multiphase core particles, the multiphase particles comprising a first material coated with at least one other material. Preferably, a surface of the multiphase particles is selected to be chemically equivalent to the dielectric layer, such as silicon dioxide, silicon nitride or low K dielectric material. For example, a multiphase particle can comprise an inorganic core particle coated with a non-soluble polymer having a chemical composition similar to the low K polymer based dielectric layer.

The concentration of the core particles in the slurry can be from approximately 1% to 40% by weight. The size of the core particles can vary from 10 nm to 10 μm.

The selective adsorption additive can be a surfactant which shows specific selective adsorption characteristics with the inorganic cores, dielectric film, refractory metal based film and metal embedded (e.g. copper or silver) film. The surfactant can be anionic, cationic, zwitterionic or non-ionic. For silica/nanoporous or silica/nanoporous silica coated inorganic cores, the preferred surfactant is cationic, zwitterionic, or a mixture of cationic/non-ionic surfactant or with a cationic surfactant with a small amount, preferably being less than 1% of an anionic surfactant.

Examples of preferred cationic based surfactants for silica include cetyl trimethyl ammonium bromide (CTAB), and cetyl trimethyl ammonium chloride (CTAC), its derivatives and chemical equivalents. The carbon chain length in the surfactant molecule is preferably from 8-20. Other examples of preferred surfactants for silicon dioxide and low K dielectrics include zwitterionic surfactants, such as KETJENLUBE 522®. KETJENLUBE 522® is the current tradename for what had been called DAPRAL GE 202®, now produced by the Akzo Nobel Functional Chemicals Company, Netherlands. This material is a water soluble copolymer of an average molecular weight of approximately 15,000 consisting of a-olefins and dicarboxylic acids, partially esterified with an ethoxilated alcohol. KENJENLUBE 522® is highly lubricating and dispersing.

For alumina-like surfaces, such as alumina particles or particles coated with an alumina layer, the preferred surfactants are anionic and zwitterionic. Examples of preferred surfactants for alumina like surfaces include sodium dodecyl sulfate (SDS), Triethanolamine lauryl sulfate, ammonium lauryl sulfate and KETJENLUBE 522®. The concentration of the surfactant can be from 0.1 of a bulk critical micelle concentration (CMC) of the solution to 1000 times the CMC. Preferably, the surfactant concentration is from 0.4 of the CMC to 100 times the CMC.

The selective adsorption additive can include at least one polymer. Polymers can be selected from polyethylene oxide (PEO), polyacrylic acid (PAA), polyacryamide (PAM), polyvinylalcohol (PVA) and polyalkylamine (PAH).

The slurry can include optional additives. Passivating additives can be provided for inhibiting the oxidation of a copper or silver containing film. Passivating additives can include benzotriazole (BTA), tolytriazole (TTA), imidazole, thiols, oxalic acid, mercaptans, sodium hexanoate and carboxylic acid. The concentration of the passivating additive is preferably from 1 mm to 1 Mole, and more preferably from 5 mM to 40 mM.

The slurry can also include at least one complexing agent. The complexing agent can be acetic acid, citric acid, tartaric acid or succinic acid. The concentration of the complexing agent can be from 1 mM to 1.0 M.

The slurry may include one or more organic solvents to add stability to the micelles. Generally, the combined organic solvent concentration should be no more than about 5% wt of the slurry. Preferred organic solvents include alcohols, such as methyl and ethyl alcohol.

The slurry can also include at least one salt for controlling the strength of the surfactant adsorption. The salt can be selected from a chloride (NaCl or KCl) a nitrate or an ammonium-based salt. Preferred salts are non-alkali salts, such as NH₄Cl, NH₄NO₃.

The pH of the slurry can be from 6 to 13. Preferably, the pH of the slurry is from 8 to 11.

The slurry preferably includes at least one oxidizer in a concentration of 0.1 to 30 weight % of the slurry. Oxidizers can include hydrogen peroxide, pottasium ferrocyanide, pottasium iodate and perchlorates. The slurry preferably forms an oxide layer on the refractory metal based film having a thickness preferable being less than about 0.2 μm.

The selective adsorption additives can exhibit substantial adsorption to a dielectric film, such as silicon dioxide or silicon nitride, with little or no adsorption to a refractory metal based film or metal gate or interconnect film, such as a copper or silver containing film. The surfactant can also exhibit adsorption to a copper or silver containing film greater than adsorption to the refractory metal based film.

The selective adsorption additive can exhibit substantial adsorption to the dielectric film, the dielectric film selected from the group consisting of silicon dioxide, silicon nitride and low K materials. The selective adsorption additive can exhibit adsorption to a copper or silver containing film greater than adsorption to the refractory metal based barrier film.

The selectivity of a CMP process using the slurry can be at least approximately 20, at least 50, preferably at least 100, more preferably at least 500, and most preferably at least 1,000 for the refractory metal based barrier film compared to a silicon dioxide or low K film. The term selectivity refers to the CMP polishing rate of the metal film when compared to the dielectric film polishing rate.

The slurry can provide a selectivity of at least 1.0 for the refractory metal based barrier film compared to a film comprising copper or silver. In another embodiment, the slurry can provide a selectivity of at least 2.0 for the refractory metal based barrier film compared to a film comprising copper or silver.

The slurry can provide a selectivity of at least approximately 20, at least 50, preferably at least 100, more preferably at least 500, and most preferably at least 1,000, for a layer comprising copper or silver compared to a silicon dioxide or low K film.

The slurry can provide an adsorption ratio (AR) for a film comprising copper or silver of no more than 3.0, the refractory metal based barrier film of no more than 5, and the dielectric film of at least 10. The AR of a material X, denoted as AR_{X}, is defined as the CMP polish rate without surfactant or polymer additive divided by the CMP polish rate in presence of the surfactant or polymer additive. The AR of the dielectric film can be at least 50, is preferably at least 100, is more preferably at least 250, and is most preferably at least 1000. The particles in the slurry can also be chosen so that the surfactant or polymer adsorption characteristics are similar to the underlying dielectric layer.

The slurry can provide an AR for a film comprising copper or silver of no more than 2, the refractory metal based barrier film of no more than 2, and the dielectric film of at least 10. In this embodiment, the AR of the dielectric film is preferably at least 100, more preferably at least 500, and most preferably at least 1000.

The slurry can provide a selective adsorption ratio for a film comprising copper or silver to the refractory metal based barrier film of at least 1.0. Selective adsorption ratios (SARs) are defined herein by comparing the adsorption ratios (ARs) of two materials, such as X and Y. The adsorption selectivity of material X compared to material Y, denoted by SAR_{X/Y} at a particular concentration “C” of the surfactant or polymer additive is what is expressed by SAR. The slurry can provide a SAR of the dielectric film to the refractory metal based barrier film of at least 10 to 50, preferably at least 100, and more preferably at least 500.

A method for chemical mechanical polishing (CMP) a structure including refractory metal based film and a dielectric film includes the steps of providing a slurry including a plurality of composite particles and at least one selective adsorption polymer or surfactant additive, the composite particles including an inorganic core surrounded by a selective adsorption additive shell. The dielectric film substantially adsorbs the selective adsorption additive, while the refractory metal based film does not substantially adsorb the selective adsorption additive. The slurry is applied to the structure. Overburden regions of the refractory metal based film are then removed using a polishing pad, the refractory metal based film generally being first converted into an oxidized form by the slurry.

The slurry can be used to implement a single step chemical mechanical polishing (CMP) process for polishing a structure which includes a gate or interconnect metal film, a refractory metal based barrier film, and a dielectric film. The one step method includes the steps of providing a slurry including a plurality of composite particles and at least one selective adsorption additive, the composite particles including an inorganic core surrounded by a shell including the selective adsorption additive. The refractory metal based barrier film and the gate or interconnect metal film do not substantially adsorb the selective adsorption additive while the dielectric film substantially adsorbs the selective adsorption additive. The slurry is applied to the structure. Initially, overburden regions of the gate or interconnect metal film are removed. Following removal of the overburden regions of the gate or interconnect metal film overburden regions of the refractory based barrier film are removed using a polishing pad with the same slurry resulting in polishing of the gate or interconnect metal film and refractory metal based barrier film in a single, preferably continuous, polishing step.

In the single step CMP process, the selectivity of the gate or interconnect metal film to the dielectric film is preferably at least 50, the selectivity of the gate or interconnect metal film to the refractory based barrier film is preferably at least 1.0 and the selectivity of the refractory based barrier film to the dielectric film is preferably at least 50. In a more preferred embodiment, the selectivity of gate or interconnect metal film to the dielectric film is at least 200. The gate or interconnect metal film can comprise copper or silver, and alloys thereof. The selective adsorbent additive can be a surfactant or a polymer and include one or more optional passivating additives, such as complexing agents, salts and oxidizers as described above.

### BRIEF DESCRIPTION OF THE DRAWINGS

A fuller understanding of the present invention and the features and benefits thereof will be accomplished upon review of the following detailed description together with the accompanying drawings, in which:

FIG. 1 shows cross sectional views after various steps in a copper damascene/CMP process.

FIG. 2 is a cross section of a CMOS transistor having a metal gate formed from a damascene/CMP process.

FIG. 3 is a perspective view of a conventional CMP polisher.

FIGS. 4(a), (b) and (c), (d) and (e) illustrate possible configurations of core particles, according to various embodiments of the invention.

FIGS. 5(a), 5(b) and 5(c) are TEM photographs of coated core particles.

FIGS. 6(a), (b) and (c) are TEM photographs of nanoporous core particles.

FIGS. 7(a), (b) and (c) illustrate some possible shell configurations for composite particles having various surfactant layer structures disposed on silica particles, while FIG. 7(d) shows selective adsorption of self-assembled surfactant molecules on a silicon dioxide surface, according to embodiments of the invention.

FIG. 8(a) illustrates a schematic diagram showing the variation of adsorption ratio (AR) as a function of concentration for metals and dielectric for two types of dielectrics.

FIG. 8(b) is a schematic diagram which shows the variation in selective adsorption ratio (SAR) of dielectrics compared to metals as a function of surfactant concentration.

FIGS. 9(a), (b) and (c) illustrate a shelled configuration for a composite particle coated with a selective adsorption additive, composite particle/surface interactions for polishing metal and dielectric layers, respectively, where the selective adsorption additive is substantially adsorbed to the particle and the dielectric, but not the metal layer.

FIG. 10 are force measurements on tantalum, copper and silicon dioxide films in a slurry containing 20 mM BTA and 16 mM C₁₂TAB at a pH of 9.

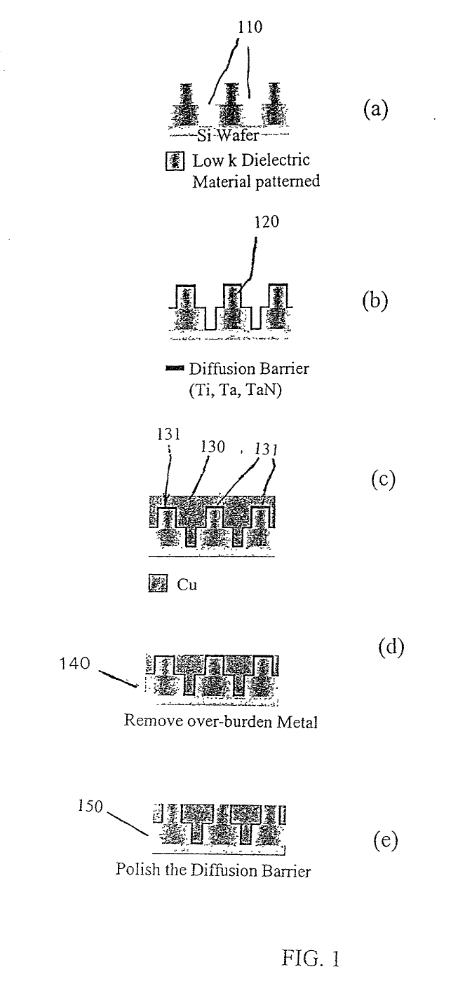

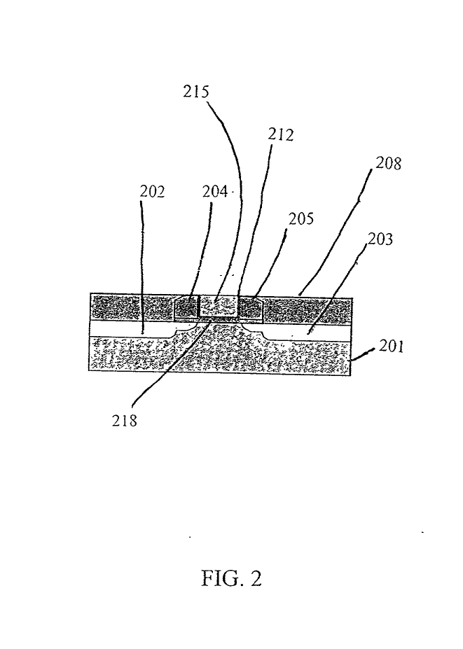

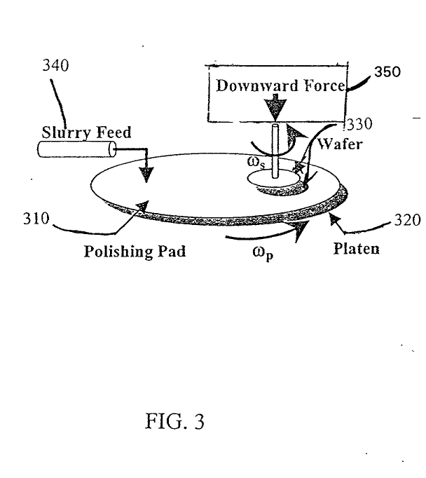

### DETAILED DESCRIPTION OF THE PREFERRED EMBODIMENTS

The invention relates to slurries for polishing structures including refractory metal based barrier layers using a chemical-mechanical polishing (CMP) process. The invention may also be used to polish both a gate or interconnect metal layer, such as copper or silver layer and alloys thereof as well as a refractory metal based barrier layer, such as Ta, TaN, WN or TiN in a single polishing step. The gate or interconnect metal layer may be embedded in the refractory metal based layer material.

The slurry is useful for polishing single or multi-level metallization that include, but is not limited to, integrated circuit metallic thin films and multi-level structures. The CMP slurry can also be used in other semiconductor processes where a copper or silver film may be required such as replaceable gate transistors in the front-end device technology, making new types of memory devices such ferroelectric devices including RAMs, high-K DRAM structures, magnetic RAMS (MRAMS), tunneling magnetoresistance devices (TMR), and giant magnetoresistance devices (GMR).

As used herein, the terms copper and copper containing alloys are used interchangeably and can be used to represent structures having gate or interconnect metal layers which have different underlying layers such as Ti/TiN/Cu, Ta/Cu, TaN/Cu, WN/Cu and X/Cu where X is Pt, Ir or W. It should be noted that the invention is also applicable for CMP of metals and metal alloys which share similar mechanical and chemical properties to that of copper and copper alloys, such as silver (Ag) and its alloys. Silver has excellent electrical conductivity and has high electromigration resistance which makes it an ideal candidate for interconnect applications. Silver can also be used as a single or multilayer electrode material in applications involving CMOS, FeRAM, TMR, and related devices. Thus, in all applications where copper is currently being used or planned for use, it is likely in the future that materials such as silver or its alloys may replace copper. Accordingly, references and examples herein relating to the CMP of copper films should be understood to include CMP of materials which share similar mechanical and chemical properties to that of copper, such as silver and silver alloys.

The term “refractory based barrier layer” is used herein to include elemental refractory metals such as tungsten, titanium, and tantalum, and refractory alloys and compounds, such as Ta₂O₅, TaN, TiN and, WN. Such refractory based barrier layer films typically underlying a gate or interconnect metal film, such as a copper containing film, such as a copper/silver containing film, or may embed a copper or silver containing film.

A chemically active slurry for the CMP of a refractory based metal barrier film includes a plurality of composite particles and at least one additive, the additive providing selective adsorption properties. The composite particles include an inorganic core, the inorganic cores coated with the additive, the additive selected to preferentially adsorb to the cores. The selective adsorption additive preferably provides non-substantial adsorption to metal or their associated metal oxide layers and substantial adsorption to underlying dielectric layers, such as SiO₂ or low K dielectric materials.

The selective adsorption additive is selected from suitable surfactants or polymer additives. As a result, the invention can provide abrasive particles that produce high shear stresses on refractory metal based barrier layers, similar or somewhat lower shear stress on gate or interconnect metal layers, such as copper, and extremely low shear stress to the underlying dielectric material. Conventional abrasive particles cannot achieve all these varying shear stress profiles for the various exposed materials at the same time.

The invention permits refractory metal based barrier film polishing by employing selective particle-surface contact. Specifically, the selective adsorption additive provided in the slurry can form self-assembled coating layers at the particle-liquid interface and the underlying insulator-liquid interface, but not at the refractory based metal-liquid interface. As a result, there is little or no abrasive contact and resulting removal of the composite particles with the insulating layer.

The CMP slurry for the polishing of refractory based metals provides selective polishing of refractory based metal containing layers with respect to gate or interconnect metals, such as copper, silver or gold, and underlying dielectric layers, such as silicon dioxide or a low K dielectric materials. A wide range of low-K dielectric materials, most having a K<3, comprised of both inorganic and organic dielectric films are currently available. These films are generally deposited using either spin-on or CVD processes.

Example of such inorganic materials include doped oxide, such as F-doped as FSG (fluorine silicate glass), H doped as HSQ, C and H doped as MSQ, HOSP, BLACK DIAMOND®, Coral® manufactured by the Novellus Corporation, San Jose, Calif. and porous silica, such as aerogels, xerogels and nanoglass. For example, TEOS (tetraethylorthosilicate) FSG (flourinated silicate glass) is a silicon dioxide based material provided by Applied Materials that has been modified by the introduction of fluorine to lower the capacitance (K-value) of the dielectric film. Organic polymers can include amorphous fluorocarbon polymers, fluorinated polyimide, PTFE poly(arylene ether), benzocyclobutene, SILK and FLARE.

By reducing the gate or interconnect metal polishing rate the surface planarity of the wafer can be considerably improved. Preferably, the slurry provides a refractory based metal/gate/interconnect metal selectivity of greater than 1 and a refractory based metal/dielectric selectivity of 20 or higher. The term selectivity refers to the ratio of the polishing rate of one film to another.

The invention can also provide a single step polishing process for a metal/barrier layer/dielectric structure, such as Cu/Ta/SiO₂ or Ag/Ta/SiO₂. A single step process as used herein refers to a polishing which utilizes a single slurry mixture, the single slurry mixture including a chemical mixture along with a fixed concentration of composite particles. The chemical mixture includes at least one selective adsorption additive and can include other optional additives, such as complexing agents and oxidizers.

The composite particles include an inorganic core surrounded by a surfactant shell provided by at least one selective adsorption additive, such as a surfactant. The selective adsorption additive is selected so that the layers to be polished, such as a refractory metal based barrier film and gate or interconnect metal do not substantially adsorb the selective adsorption additive, while the selective adsorption additive adsorbs strongly on the underlying dielectric layer, such as SiO₂ or a low K dielectric layer. As used herein, the term “low K dielectric” refers to a dielectric material having a dielectric constant of approximately 4, or less, such as Black Diamond®. This leads to significant polishing of the refractory metal based barrier film and gate or interconnect metal, but no significant polishing of the underlying dielectric layer.

In the preferred embodiment of the invention, the slurry particles are selected to have a surface composition that matches the underlying dielectric material. In this preferred embodiment, the surface chemistry for the selective adsorption additive, such as a surfactant, can be the same with respect to the slurry particles and the underlying dielectric layer.

Matching the surface chemistry of the slurry particles and the dielectric material surface results in repulsion of the slurry particles from the dielectric surface. As a result, the dielectric polishing rate can be very low. For example silica particles are preferably selected if SiO₂ or a doped silica or porous silica is the underlying dielectric material. Alternatively, coated particles can provide matched surface chemistry to that of the underlying dielectric material by using non-silica particles cores, such as alumina coated with silica to produce essentially equal adsorption of the selective adsorption additive on the slurry particles and the dielectric layer. Substantial adsorption of the additive can provide two other functions. It can stabilize the slurry as well as reduce the particle contamination on the wafer surface after completion of the CMP process.

In the case of a tantalum based barrier material, the slurry generally provides an oxidant to oxidize the tantalum (or other refractory metal) to tantalum oxide to ease removal. However, tantalum oxide is a comparatively hard material. Accordingly, conventional soft slurry particles cannot generally remove tantalum oxide or other refractory metal oxides. Typically, to increase the stress on the barrier layer surface to facilitate efficient polishing, silica, alumina, titania or other hard abrasive particles are added to the slurry. It is known that larger sized particles result in larger stresses on surface films, thus being better able to better dislodge the oxide film from the tantalum surface. However, it is known that larger particles generally lead to more scratching.

Larger particles also increase the removal rate of interconnect or gate level metal such as copper, since stress assisted removal of surface layers is the generally the primary CMP removal mechanism. Abrasive particles can also result in rapid removal of the underlying insulating layer (e.g. silicon dioxide or a low K dielectric) once the refractory metal based barrier layer is polished off. Thus, use of a conventional refractory metal based slurry containing large particles cannot provide the desired results of reduced removal of copper and insulating layers during refractory metal based polishing and limited scratching.

Abrasive particle interaction with soft insulating layers, such as silicon dioxide, besides resulting in scratching, can also lead the peeling of insulating film. This problem worsens as the particle hardness increases. Ideally, a barrier layer CMP slurry would provide abrasive particles that produce high shear stresses on refractory based barrier metals and interconnect or gate level metals, such as copper, and extremely low shear stress to the underlying insulating dielectric material. A conventional abrasive particle based CMP process cannot achieve all these varying shear stress profiles for various materials at the same time that a CMP process which utilizes composite particles according to the invention can provide.

The concentration of composite particles is generally from 1 to 40 wt. %. A preferred concentration range for composite particles is between 3 to 20 wt. %.

The inorganic composite particles cores can be selected from at least five different types of particles. The cores can be inorganic single-phase particles, coated (multiphase) core particles, metal particles, mixed composite particles and nano-porous particles, or mixtures thereof. All the particle types can be made from known techniques, such as liquid based processes, gas based processes and dry/wet milling based processes.

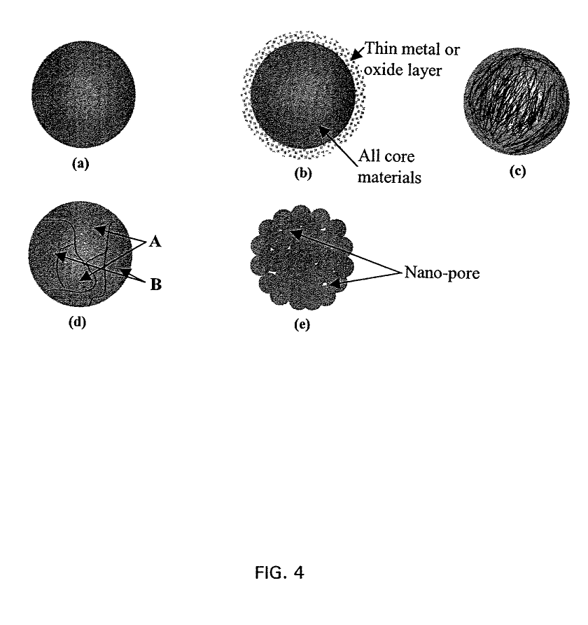

The primary size of the core particles can vary from 5 nm to 50 microns. The preferred size is between 30 nm to 300 nm. The primary particle size refers to the minimum unaggregated size of the particles. A pictorial representation of cores made up of the five different material types, being inorganic single-phase particle, coated particle, metal particle, mixed composite particle and nano-porous particle are shown in FIGS. 4(a), (b), (c), (d) and (e), respectively.

The cores of the composite particles can be selected to achieve desired mechanical, surface chemical and selective adsorption additive (surfactant or polymer) adsorption characteristics, respectively. For example, if a particular hardness and surface characteristic is desired, the inorganic core can be composed of a hard core, such as alumina, silicon nitride, and coated with a thin layer, such as silicon dioxide, low K dielectric or a non-soluble polymer, which mimics the composition of the dielectric layer. Thus, particles with specific desired mechanical and additive adsorption properties can be obtained. The mechanical properties of the composite particles are primarily controlled by the properties of the bulk material comprising the core, but the surfactant adsorption properties are controlled by the coated layer on the surface of the core particle.

It may also be possible to change the additive (surfactant or polymer) adsorption site density at surfaces including the surface of the core particle. This can be done by forming a composite core particle from two or more distinct phases or having a nanoporous particle structure. If a hydrophobic surface is desired, a metal or graphite particle or a non-soluble polymeric coating on the core particle can be used.

Single-phase inorganic particle can be selected from materials, such as silica, zirconia, yttria, alumina, titania, silicon nitride, silicon carbide or its mixtures. Multiphase core particles can be particles with an internal composition of either silica, zirconia, alumina, titania, silicon nitride, silicon carbide, ceria and manganese oxide or its mixtures having at least one optional solid coating of a thin layer of a metal, semiconductor or an oxide of these materials. Metal particles can include aluminum, titanium, copper or their alloys, while semiconducting particles can include silicon. These materials can include a surface thin oxide layer on their surface. The thickness of the coatings can vary from 0.5 nm to 500 nm. Regardless of whether single phase cores or multiphase cores are used, the selective adsorption additive is disposed on the surface of the respective particles.

The preferred thickness of the solid coating is between 10 nm to 100 nm. The solid coating can be of zirconia, alumina, titania, silicon nitride, silicon carbide, polymeric materials and its mixture, its composition being different from its internal (core) composition. The coatings can be continuous or discrete and provide 10 to 100% core particle surface area coverage. The coatings preferably have different surfactant characteristics compared to the bulk material comprising the particle.

Nano-porous particles may be particles providing nanosized pores having sizes varying from 0.21 nm to 30 nm in particles, such as silica, alumina and titania. The pore volume can vary from 0% to 80% of the total volume of the porous particles.

Preferred examples of single phase core particles include compositions similar to the underlying dielectric material such as silicon dioxide, doped silicon dioxide, carbon doped silicon dioxide. A preferred single-phase core particle is silica. A preferred multiphase particle is alumina or silica coated with layer with similar composition as the underlying dielectric layer such as silica, low K dielectric layers, doped silica, carbon doped silica, nano-porous silica or a low K dielectric layer. More preferred multiphase core particles include alumina coated with silica, silica coated with nano-porous silica, and silica coated with cerium oxide.

A preferred example of a two phase composite particle is silica and silicon nitride. A preferred example of a nano-porous particle is silica with porosity varying from 1% to 80% of the total volume.

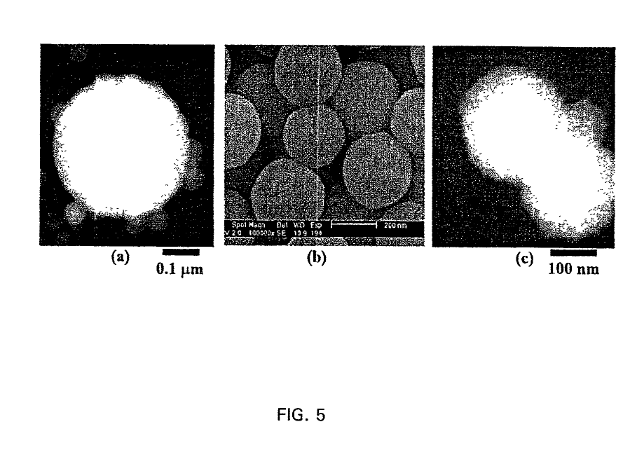

FIGS. 5(a), (b) and (c) show TEM photographs of various coated core particle structures. FIG. 5(a) shows an alumina particle coated with silica, while FIGS. 5(b) and 5(c) show examples of a silica particle coated with a nano-porous silica material and silica particle coated with cerium oxide, respectively. All three coatings were formed by wet precipitation techniques. The coating thickness varied from 0.5 nm to 50 nm. By applying a solid coating to form multiphase core particles, both the bulk mechanical properties and the surface adsorption properties of the particles can be tailored.

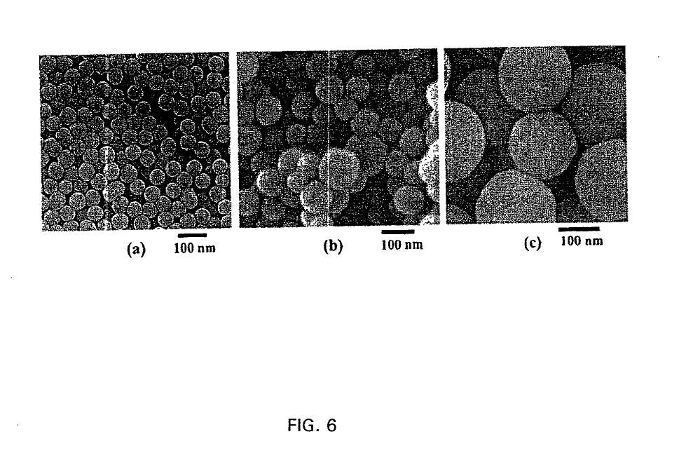

Nano-porous silica particles can be formed by a modified Stober process (W. Stober, A. Fink, E. Bohn, J. Colloids and Interfacial Science, 26, 62-69 (1968)). The particle size can vary from 200 nm to 500 nm, while the porosity can vary from 10 to 60%. As the porosity of the surface increase the number of adsorption sites are expected to increase. FIG. 6 shows TEM photographs showing different sizes of nanoporous core particles. The particles are mono-dispersed and spherical in nature. It is noted that the aspect ratio of particles can be changed using alternate formation methods.

The selective adsorption additives preferably provide several characteristics. First, the selective adsorption additives should substantially adsorb on the inorganic single or multiphase core particles in the slurry, to form a soft shell with a relatively immobile individual surfactant or polymer additive layer or relatively immobile self assembled structures, such as micelles. Similar adsorption characteristics on the polymer also lead to formation of similar structures. The selective adsorption additive should not substantially adsorb onto the gate or interconnect metal, such as copper, or the refractory metal based barrier layer, such as tantalum.

Preferentially adsorption of the selective adsorption additive to the single phase or multi-phase core particle forms composite particles having a core coated with a soft shell. The hard core layer refers to a hardness greater than 2.0 on Mohs scale, while a soft shell refers to a hardness less than 2.0 on a Mohs scale. To form the hard core-soft shell structure, a selective adsorption additive selected from surfactants and polymer additives is added to the slurry. The surfactant or the polymer additive is selected to provide specific adsorption characteristics, the adsorption characteristics regulating the polishing characteristics of the slurry.

The surfactant or polymer is preferentially adsorbed to the core particles and the underlying dielectric, such as SiO₂, doped SiO₂, nanoporous silica, or a low K dielectric material. The surfactant/polymer additive should be not substantially adsorbed to the layers which are to be polished, such as a gate or interconnect metal layer (e.g. copper or silver) and refractory based barrier layers (e.g. Ta).

The adsorbed surface layer disposed on the core particles or the underlying substrate may be in the form of partial layer coverage or in the form of the three-dimensional self assembled layer on the surface. Examples of three-dimensional self-assembled layers include, bilayers, spheres, hemispheres, cylinders, and rods, reverse micellular structures. If used, polymeric additives can attach to the surface can be in the form of coils or in form of flattened or extended structures.

The removal of the generally mechanically hard and chemically passive refractory metal based barrier layers, such as tantalum, is more easily achieved if the surface of the barrier layer is oxidized to tantalum oxide. For example, tantalum oxide can more easily be readily removed compared to metallic tantalum by CMP processing.

The chemicals for oxidizing the refractory metal based barrier layer and metal films can be standard oxidizers, such as hydrogen peroxide. Examples of other oxidizers include pottasium ferrocyanide, pottasium iodate and related oxidizers, such as perchlorates. The concentration of oxidizers preferably is from 0.1 to 30 wt. %. Under these conditions, both the refractory based metal, such as tantalum, and interconnect or gate metal, such as copper, form respective oxide layers.

It is generally preferable for the slurry to produce a barrier layer oxide layer thickness of from approximately 1 to 200 nm. To limit the thickness of the oxide layer formed, oxidation inhibitors can be added to the slurry, such as BTA. If the oxide layer is too thin, the CMP removal rate will generally be too low.

As copper or other metal lines are generally present on the wafer, there may be a need to passivate the metal (e.g. copper) lines during CMP process. If the barrier layer (e.g. Ta) polishing rate is reduced, then the selectivity of the barrier layer polishing process will also decrease. The lack of a surface modified layer may also create scratches on the surface. Thus, defectivity can be expected to increase. If the oxide thickness is generally greater than 200 nm, the planarity of the process can be compromised. Good planarity can reduce the surface defectivity such as dishing and erosion.

Both dishing and erosion defects are generally present on the incoming wafers which arrive for barrier layer polishing. Incoming wafers have defects because the slurry used for metal CMP, such as copper CMP generally has a higher polishing rate for the metal as compared to the barrier layer. To reduce the dishing and erosion, a barrier layer CMP slurry preferably has a lower polishing rate for metals, such as copper, as compared to barrier layers, such as tantalum.

The pH of the slurry can also play a significant role in barrier layer CMP characteristics. For example, the pH under which both tantalum and copper form oxide layers is between approximately 6 to 13. Preferably, the pH is held between 8 to 11 because of enhanced adsorption of surfactants or polymer additives on silicon dioxide and the stability of the slurry in a neutral to alkaline pH.

It is also desirable to ensure that the slurry particles are stable in a colloidal suspension in the normally high ionic strength slurry. This can be difficult because the high ionic strength of the slurry can shield the electrostatic charges in slurry, which are critical in maintaining the slurry stability. The theory of Derjaguin, Landau, Verwey and Overbeek (DLVO theory) predicts suspension stability when the surface charge of the particles are high and the formation and overlap of the electric double layer between two particles prevents agglomeration of the particles. However, the presence of salts in high ionic strengths can screen the surface charges and destabilize the slurry. The substantial adsorption of the surfactant/polymer additives onto the dielectric layers and the inorganic core particles helps maintain the stability of the slurry.

To be able to achieve the wide range of variability in the particle interactions with different layers for refractory metal based film polishing, the invention provides a slurry including a plurality of composite particles, the composite particles comprising core abrasive particles surrounded by a soft shell of a self-assembled surfactant or polymer layer. In the case of surfactants, self-assembled surfactant layers can be in the form of aggregates, known as micelles.

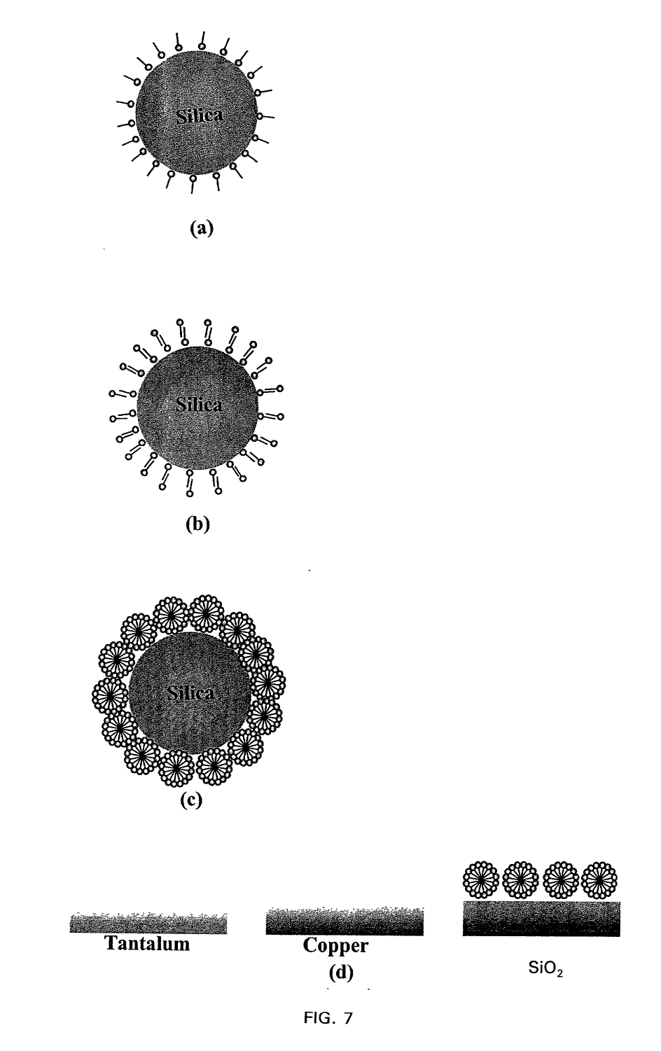

The shape of the micelles can vary from cylindrical, spherical, bilayer, hemispherical or other shapes, depending on factors such as the nature of the interaction with the wafer surface, the concentration of surfactant, the presence of ions, and the nature of the head and tail group of the surfactants. FIGS. 7(a), (b) and (c) show some possible configurations of composite particles suitable for use in a slurry, the composite particles having various surfactant layer structures disposed on silica particles. In each configuration shown, the silica particles are surrounded by a surfactant shell.

FIG. 7(d) illustrates selective adsorption of surfactant particles shown in FIG. 7(c) on a silicon dioxide surface, but not on a tantalum or a copper surface. Selective adsorption permits selective polishing of layers which do not substantially adsorb the surfactant (Cu, Ta) while not substantially polishing the silicon dioxide surface.

The surfactants or polymers preferably provide selective adsorption characteristics on different surfaces exposed to the slurry. For example, the surfactant or polymer preferably provides strong adsorption to the slurry particles and underlying insulating dielectric layers, such as silicon dioxide. The formation of a selective highly adsorbed layer on the slurry particles and the dielectric surface leads to several helpful properties.

Slurry stability can be improved by the surfactant because the surfactant or polymer coated particles repel one another and as a result tend not to agglomerate. This repulsion is due to steric forces. The dielectric layer remains substantially unchanged by the refractory metal polishing process because there is essentially no particle-surface contact at the dielectric surface. As a result, there is little or no scratching or peeling of the dielectric layer. The dielectric surface may also be cleaned during barrier layer polishing due to repulsion of particles from the dielectric surface. Thus, the formation of the composite particles having a hard core and soft additive shell and strongly adsorbed surfactant layer on insulating surfaces results in improved CMP barrier layer results.

To ensure that the composite hard core-soft shell particles are optimized for CMP polishing of refractory based barrier layers on circuits for applications when copper films are present, it is preferable to provide high polishing rates for refractory metal based barrier layer relative to the polishing rate for copper or other metal. This can be achieved by providing composite slurry particles coated having a surfactant or polymer coating, where the refractory metal based barrier layer film adsorbs little or no surfactant, while the copper or other metal layer adsorbs more surfactant as compared to the tantalum film. Thus, an additive which provides substantial adsorption on the underlying dielectric surface, some adsorption on the copper or other metal film surface and little or no adsorption on the refractory metal based barrier layer film can be used to provide an optimized barrier layer polishing process.

A variety of surfactants which can be used with the invention. Surfactants can either be cationic, anionic, zwitterionic or non-ionic. The surfactants can be used individually or in a mixed state. A list of surfactants which can be used with the invention is provided in a book by M. J. Rosen, Surfactants and Interfacial Phenomena, John Wiley & Sons, 1989, hereinafter Rosen, on pgs. 3-32, 52-54, 70-80, 122-132, and 398-401.

Surfactants are generally characterized by a hydrophilic head group and a hydrophobic tail group. Examples of tail groups include straight chain, long alkyl groups (carbon chain length varies from C₈ to C₂₀), branched chains, long chain (C₈-C₁₅) alklybenzene residues, long chain perfluoroalkyl groups, polysiloxane groups, high molecular weight propylene oxide polymers.

Examples of anionic surfactants include carboxylic acid salts, amine salts, acylated polypetides, sulfonic salts, higher alkylbenzene sulfonates, secondary n-alkanesulfonates, sodium alkene sulfate (SAS), sodium dodecyl sulfate (SDS), olefin sulfonates (AOS), sulfosuccinate esters, sulfated linear primary alcohols, sulfuric acid ester salts, phosphoric amides, polyphosporic acid esters and perfluorinated anionics. Preferred anionic surfactants include SDS and SAS and their alkali free derivatives.

Examples of cationic surfactants include long chain amines and their salts, diamines and polyamines and their salts, quaternary ammonium slats, polyoxyethylenated (POE) long chain amines, quaterized polyoxyethylenated long chain amines, amine oxides and cetyl trimethyl ammonium (CTAB). Preferred cationic surfactants include dodecyl trimethylammonium bromide (C₁₂TAB) and related compounds, such as C₈TAB, C₁₀TAB, C₁₄TAB, C₁₆TAB, C₁₈TAB, with varying hydrophobic chain lengths. Other preferred examples of cationic surfactants include dodecylammonium chloride, cetylpyridium bromide. In each of these cases, the hydrophobic chain length is preferably varied from C₈ to C₂₀.

Examples of zwitterionics include B—N alkylaminopropionioc acids, N alkyl-B. iminodipropionic acids, imidazoline carboxylates, N-alkylbetanies, amine oxides, sulfobetanies and DAPRAL® variants. A preferred zwitterionic surfactant is KETJENLUBE 522®.

Examples of non-ionic surfactants include polyoxyethlyenated alkylphenols, alkylphenol, polyoxyethlyenated straight chain alcohols, polyoxyethlyenated polyoxypropylene glycols, polyoxyethlyenated mercaptans, long chain carboxylic acid esters polyoxyethlyenated silicones, tertiary acetylenic glycols and TRITON X-100® manufactured by the Dow Chemical Corporation, MI. TRITON X-100® is octylphenol ethylene oxide condensate and is also referred to as Octoxynol-9. This material has a molecular weight of 625 amu.

Preferred examples of non-ionic surfactants include TWEEN-80® and the family of TRITON X® compounds. TWEEN-80™ is manufactured by the ICI group of Companies, NewCastle, Del. TWEEN 80® is polyoxyethylene sorbitan monooleate, and has the following synonyms: TWEEN 80® 1, polyoxyethylene sorbitol ester; polysorbate 80 and PEG (20) sorbitan monooleate. This material has the molecular formula C₆₄H₁₂₄O₂₆₃ and a corresponding molecular weight of 13103 amu.

A preferred embodiment of the invention uses silica or silica inorganic cores coated with surfactants to form a hard core-soft shell structure. The inorganic core can be silica, doped silica, porous silica, or hard particle (Mohs hardness greater than 3.0) coated with silica, doped silica, or a porous silica layer. For silica/nanoporous or silica/nanoporous silica coated inorganic cores the preferred surfactant is cataionic, zwitterionic, or a mixture of cationic/non-ionic surfactant or with a cationic surfactant with generally less than 1% of an anionic additive. Examples of preferred cationic based surfactants for silicon dioxide include CTAB, and CTAC, and their derivatives and chemical equivalents. The carbon chain length in the surfactant molecule is preferably from 8 to 20. Other examples of preferred surfactants for silicon dioxide include zwitterionic surfactants, such as KETJENLUBE 522®. The concentration of the surfactant can be from 0.1 of a bulk critical micelle concentration (CMC) of the solution to 1000 times CMC. Preferably, the surfactant concentration is from 0.4 of the CMC to 100 times CMC. The bulk CMC value of the surfactant is defined as the minimum concentration at which the surfactant self assembles to form structured layers in a bulk solution.

In each of these surfactants, the head group and the tail group can be varied to provide similar effects in the slurry but at different concentration levels. In certain cases it may be advantageous to use mixed surfactants to control the adsorption density, the strength of the surfactant adsorption. Examples of some possible synergistic effects are given on pg. 398-401 of Rosen. Additionally some salts as outlined earlier may be added which control the strength of the surfactant adsorption.

Organic solvents may be added to the slurry to add stability to the micelles. Generally, the organic solvent should be no more than about 5% wt of the slurry. Preferred organic solvents include alcohols, such as methyl and ethyl alcohol.

The surfactant additives described above can be supplanted or used in combination with polymeric additives such as polyethylene oxide (PEO), polyacrylic acid (PAA), polyacryamide (PAM), polyvinylalcohol (PVA), polyalkylamine (PAH) and related polymeric compounds. These polymer additives can be used as dispersants for particles in the slurry. The molecular weight of these additives can be varying from 500 to 100,000 amu. The concentration of these additives can vary from 1 mg/liter to 10 g/liter.

Polymeric additives are generally chosen based on the nature of the surface sites for polymeric adsorption. For example if silica surface based slurry particle cores are used, the preferred choice of additives are PEO, and PVA. If silicon nitride slurry particle cores are used, then preferred polymer additive is PAA, which generally strongly adsorb to the silicon nitride cores. For the metal layers such as copper, tantalum and silver, several mercaptans, and thiol based compounds can be readily adsorbed to theses surfaces and can be readily used to modulate the polishing characteristics.

Additionally, some salts may be added to control the strength of the surfactant adsorption. In some of these examples, hydrophilic head groups contain alkali metals such as Na and K. However, it may be possible to replace the alkali metals with other ions (such as ammonium based) which may be more compatible with semiconductor processing.

The concentration of surfactants used depends on the type of the surfactant used, the surfaces of particles and wafers such as copper, tantalum, silicon oxide, low K dielectric which the slurry is contact with, and CMC value of the surfactant. At low concentration, the surfactant may adsorb onto the solid surfaces in a patchy manner and change the electrostatic properties and the surface energy of the surface. The adsorption of the surfactant may reduce the etching of the surface layer. At higher concentration of the surfactant, the surfactant molecules may coalesce together to form self assembled structures.

Examples of structured surfactants can include spheres, cylindrical rods, bi-layers, disks and vesicles. Once the bulk CMC is reached, the surface tension of the solution does not generally decrease further, but is accompanied by a rapid drop in the electrical conductivity of the bulk solution. The formation of micelles is thought to be due to the reduction in the free energy of the solution.

The adsorption of surfactant and its self assembly can be measured by a combination of several techniques including Fourier transform infrared spectroscopy (FTIR), adsorption density measurement via solution the depletion method, contact angle measurements and surface force measurements via atomic force microscopy (AFM). The confirmation of micelles at the surface and the bulk of the solution can be investigated using FTIR, AFM, and electrical conductivity and surface tension/contact angle measurements.

The concentration of the surface-active selective adsorption additives is generally provided such that the surfactants are strongly adsorbed to the surface of the particle cores and the underlying dielectric. The concentration in which the micelles form in the bulk of the materials (CMC) varies with the hydrophobic tail and hydrophilic head groups of the surfactant, and presence of the other additives in the solution. The strength of the surfactant adsorption on the surface of the particle or the dielectric surface depends on the density and the nature of adsorption sites on the surface and the chemistry of the solutions.

If polymer additives are used, the concentration of the polymer additives preferably varies from 1 mg/liter to 2 gm/liter of solution. A preferred concentration of the polymeric additives varies from 10 mg/liter to 1 gm/liter. The molecular weight of the polymeric additive can vary from 500 to 100,000 amu. The preferred molecular weight of the additive varies between 1000 to 10,000 amu.

The surfactants or polymeric additives can exhibit substantial adsorption to the dielectric film such as silicon dioxide or silicon nitride or low K dielectrics such as doped silica, nanoporous silica and certain polymers, and little or no adsorption to the gate or interconnect metal layer and the refractory based barrier layer. The surfactant film can also exhibit adsorption to the gate or interconnect metal layer greater than the adsorption to the refractory based barrier layer, such as a tantalum containing film. As a result, the CMP rate of the tantalum film can be higher than the copper film. The CMP rate of both the metal films should be much higher than the dielectric polish rate due to the selective adsorption characteristics.

To quantify the selective adsorption characteristics of surfactants or polymers additives, this application will define certain new terminology in relation to new measurement techniques. Standard measurement techniques and measures of adsorption density of surfactants use solution depletion methods, contact angle or zeta potential or atomic force microscopy (AFM) methods. These conventional methods have been found to be inadequate to describe the effects of adsorption phenomena on resulting CMP characteristics. Some of the shortcomings of conventional measurement methods include the inability to conduct measurements in actual CMP conditions where interactive effects may play a critical role. Moreover, conventional methods produce results which generally lack correlation with the CMP polishing rate. As described below, new variables have been defined herein, such as adsorption ratios (AR) and selective adsorption ratios (SAR) to correspond to parameters measured when using the new measurement techniques.

The adsorption and the selective adsorption characteristics of surfactants and polymer additives on various surfaces when immersed in a slurry can be defined by the adsorption ratios (AR) and selective adsorption ratios (SAR), respectively. The adsorption ratio of a material X is denoted as AR_{X} and is defined as the CMP polish rate without surfactant or polymer additive divided by the CMP polish rate in presence of the surfactant or polymer additive. The AR is generally always greater than or equal to 1, since the polishing rate of a given material can only generally decrease upon the addition of a surfactant or a polymer additive which exhibits surfactant-like properties. In cases where the surfactant destabilizes slurry, the AR values can be less than 1.0.

AR_{X}(C)=(CMP Polish Rate without surfactant)/(CMP Polish Rate with surfactant).

Where C corresponds to the concentration of the surfactant or polymer additive. The AR parameter also permits an objective definition of what constitutes substantial adsorption of an additive in relation to one or more layers. As noted earlier, “substantial adsorption” relative to a given layer refers to a CMP polishing rate (for a given slurry and CMP polishing conditions) with the selective adsorption additive being less than or equal to 1/3 of the CMP layer polishing rate when the slurry does not include the selective adsorption additive. This can be equivalently stated as a CMP polishing rate without the selective adsorption additive being at least three (3) times the CMP polishing rate with the selective adsorption additive.

In the case of strong adsorption of the selective adsorption additive, such as by a dielectric layer, AR values can be at least 50, preferably greater than 100, and even 1,000 or more in certain embodiments. This condition typically occurs when the adsorption additive show substantial adsorption to both the dielectric and the inorganic core particle. On the other hand, non-substantial adsorption relative to a given film refers to a CMP polishing rate (for a given slurry and CMP polishing conditions) without the selective adsorption additive being less than or equal to three (3) times the polishing rate of the layer with the selective adsorption additive.

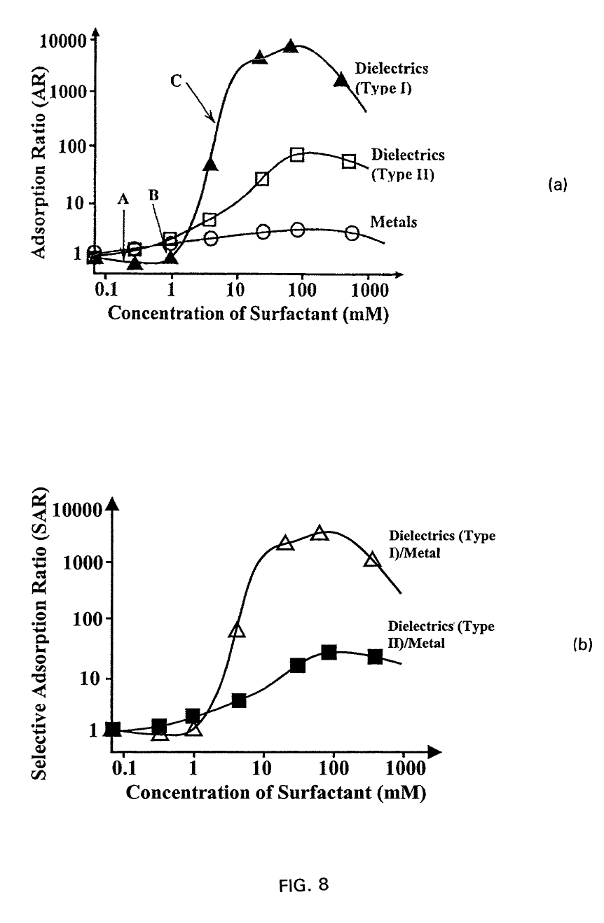

FIG. 8(a) shows data for the variation in adsorption ratios as a function of surfactant concentration for dielectrics such as SiO₂, doped SiO₂ (Type 1 dielectric) and low K materials such nanoporous silica and polymers such SILK®, FLARE® (Type II dielectric) as well as for gate or interconnect metal layers and refractory based barrier layers (metals). The diagrams reflect the general trend in adsorption ratios for different type additives, such as surfactants and polymers.

As seen in FIG. 8(a), AR values do not change linearly with concentration, but in a rather complicated manner. The complicated nature may be due to different phenomena which occur on the particle as well as the polishing surfaces, and as the concentration of the surfactants or polymer additives are varied. For example, AR value can decrease with addition of additives (point A) due to destabilization of particles in the slurry due to partial adsorption.

The AR ratios may increase rather suddenly with slight increase in concentration as shown (point B) due to formation of micelles and fixation of micelles on the surface of solid surfaces. In other cases, such as point C, the change in AR is basically linear in nature signifying a linear-like effect, such as a linear increase in surface coverage.

As the AR increases, a higher adsorption of the additive on the surface of the film or on the particle surface generally results. Besides the accompanying change in the CMP polishing rate, the AR ratio can also be used as a guide to determine other properties of the slurry. Generally, the higher the value of AR, the higher the stability of the slurry. Thus, particle contamination on the surface of a dielectric after CMP polishing can generally be kept at a minimum through the use of surfactant or polymer additives. The other salient aspects of particle defectivity including, scratches and dents, will also generally decrease with increasing AR values. In addition, the planarity of the metal and dielectric polish generally improves with increasing AR values. Besides enhancing the selectivity of the polish, higher AR values are expected to lead to other beneficial properties including slurry stability, reduced surface defectivity of the dielectric and enhanced planarity of polishing.

Preferably, surfactants or polymer additives are added to the slurry solution such that the AR values of the underlying dielectric is kept large, typically greater 100, while the AR values of the metal is typically kept generally below about 5.0. This large difference in AR generally occurs above a particular concentration (critical) of the selective adsorption additive. High AR for the dielectric layer relative to the metal layers insures that the polishing rate of the dielectric is much lower than the metal layers. C_{critical} also defines the minimum concentration of surfactant needed to achieve optimum polishing. C_{critical} is dependant on the type of surfaces, nature of the particle core of the core-shell particles and presence of other optional additives which may be included in the slurry. C_{critical} values have been found to generally vary from 10% of bulk CMC to over 100 times the bulk CMC value of the surfactant. In case of the polymer additive, no CMC value exists, however the concentration is typically greater than 1 gm/liter.

Using specific surfactants and polymer additives, values of AR_{Ta} were found to vary from 0.5 to 5.0, AR _{Dielectric} was found to vary from 0.5 to over 10,000, while the AR values for copper and silver were found to vary from 0.5 to 5.0. Accordingly, a slurry can be configured to produce high AR _{Dielectric} values to permit high metal polishing rates relative to the dielectric.

Selective adsorption ratios (SARs) compare the adsorption ratios of two materials, such as X and Y. The adsorption selectivity of material X compared to material Y, denoted by SAR_{X/Y} at a particular concentration “C” of the surfactant or polymer additive is defined as the value of AR_{X} divided by the value of AR_{Y}:

SAR_{X/Y}(C)=AR_{X}(C)/AR_{Y}(C)

Both AR_{X}(C) and SAR_{X/Y}(C) are generally a function of the type and the concentration (C) of the surfactant or polymeric selective adsorption additive. The higher the SAR, the higher the selectivity of additive adsorption. If Y is a metal, such as Ta, Cu or Ag or alloy thereof, while X is a dielectric such as silicon dioxide or a low K dielectric, to achieve high SAR_{Dielectric/metal} values it is necessary to have high values of AR_{Dielectric} and low values of ARₘₑₜₐₗ. Thus, the selective adsorption additive is preferably selectively adsorbed by the dielectric to achieve high SAR_{Dielectric/metal} values. In experiments performed, SAR_{Dielectric/Ta}, SAR_{Dielectric/Cu}, SAR_{Dielectric/Ag} were found to vary from 1.0 to over 4,000. The SAR_{Ta/CU} was found to vary from 0.3 to 2.0.

FIG. 8(b) is a schematic diagram which shows the variation in selective adsorption ratio (SAR) of dielectrics compared to metals as a function of surfactant concentration. FIG. 8(b) is derived through point by point calculation (SAR_{X/Y}(C)=AR_{X}(C)/AR_{Y}(C)) from data provided in FIG. 8(a). As noted above, Type 1 dielectrics include SiO₂, doped SiO₂, while Type II dielectrics include low K materials such nanoporous silica and polymers such SILK®, FLARE®.

The selectivity of CMP polishing of material X divided by the CMP polish rate of material Y at a concentration “C” of the surfactant or polymer additive is denoted herein as S_{X/Y}(C), and can be expressed by the following equation:

S_{X/Y}(C)=SAR_{Y/X}(C)×S_{X/Y}(0)

Where S_{X/Y}(0) is the ratio of the CMP polish rates of material X and Y when no polymeric or surfactant selective adsorption additives are added to the solution. It is noted that SAR_{Y/X}(C)1/SAR_{X/Y}(C). This equation shows that to achieve high selectivity the additive should generally be chosen so that the SAR values and the selectivity at zero concentration should be maximized. The equation for copper/dielectric, tantalum/dielectric selectivity, silver/dielectric selectivity can be represented as shown below:

S_{Cu/Dielectric}(C)=SAR_{Dielectric/Cu}(C)×S_{Cu/Dielectric}(0)

S_{Ta/Dielectric}(C)=SAR_{Dielectric/Ta}(C)×S_{Ta/Dielectric}(0)

S_{Ag/Dielectric}(C)=SAR_{Dielectric/Ag}(C)×S_{Ag/Dielectric}(0)

S_{Cu/Ta}(C)=SAR_{Ta/Cu}(C)×S_{Cu/Ta}(0)

S_{Ag/Ta}(C)=SAR_{Ag/Cu}(C)×S_{Ag/Ta}(0)

Thus, to remove a tantalum barrier layer for example, the S_{Cu/Dielectric}(C), S_{Ta/Dielectric}(C) values should preferably be kept high, such as at least 50 to 100, while the S_{Cu/Ta}(C) should preferably be kept less than 5.0. These parameters have similar values if copper is replaced by silver. It should be noted that Ta is a representative example for most refractory metal comprising layers.

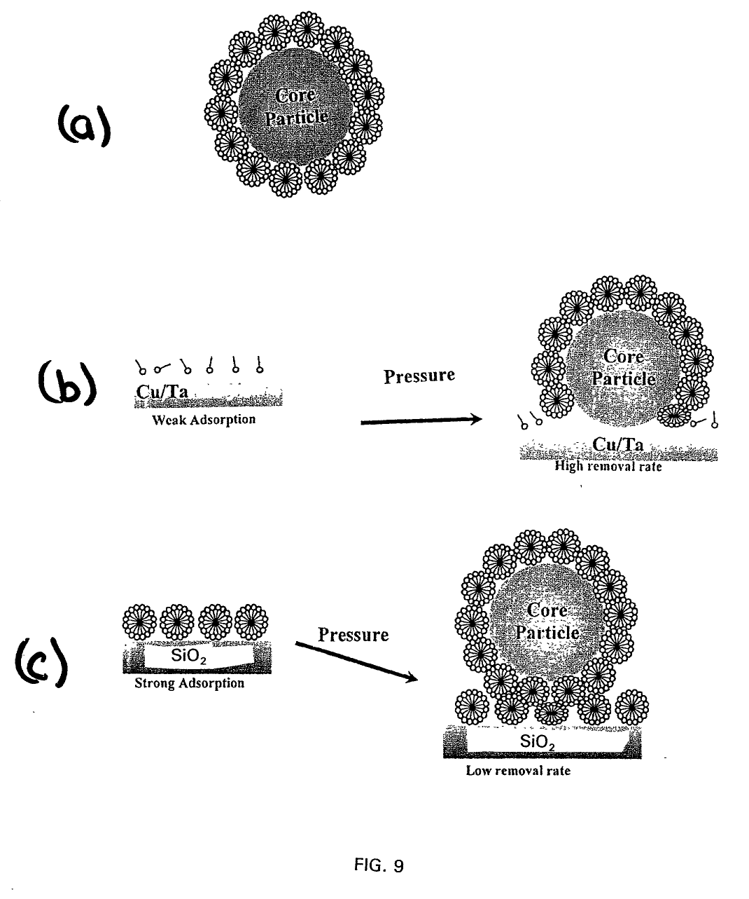

FIG. 9(a) shows a schematic of a shelled configuration for a composite particle coated with a selective adsorption additive. FIGS. 9(b) and (c) shows the interaction of the particle shown in FIG. 9(a) with metal (Cu or Ta) and a dielectric layer (SiO₂ or a low k dielectric). The surfactant or polymer additive is chosen to strongly adsorb to the core particles (FIG. 9(a)) and the underlying dielectric layer (FIG. 9(c)), and to weakly adsorb to Cu and Ta (or other refractory metal based layer). Thus, the surfactant preferably possesses a large AR value for the dielectric and low AR values for the respective metal layers. This also results in a large SAR of metals compared to the dielectric. As a result, a polishing process using the particles shown can provide a high metal to dielectric selectivity.

During CMP polishing, the weakly adhered selective adsorption additive layer on the metal are generally removed by the applied pad pressure, while the strongly adsorbed layers on the slurry particles and the dielectric layer are generally not removed. This results in a high polishing rate for the metal and a low polishing rate for the dielectric. Experiments performed which used varying selective adsorption additives demonstrated a selectivity of a gate or interconnect metal layers such as Cu and Ag and refractory based metal layers, such as Ta from 10 to greater than 1000 relative to silicon dioxide.

Passivating chemicals can be added to the slurry along with the selective adsorption additive to further inhibit the oxidation of gate or interconnect metal layer metals and to enhance the surface finish of the gate or interconnect metal layer while not substantially affecting the removal rates of the refractory metal based barrier layer film or dielectric film, such as silicon dioxide. As a result, the polishing rate of a gate or interconnect metal layer, such as copper, can be selectively reduced.

Some of the passivating additives, sometimes referred to as inhibitors, include surfactants and mercaptan based chemicals. For example, passivating additives for copper include benzotriazole (BTA), tolytriazole (TTA), imidazole, thiols, mercaptans, oxalic acid, sodium hexanoate, carboxylic acid, and their derivatives.

The preferred passivating additives are BTA, TTA, imidazole and mercaptans. For example, the preferred concentration of additives, such as BTA, can be from 1 mM to 1 Mole, while a more preferred passivating additive concentration is from 5 mM to 40 mM.

The concentration of oxidant can also be used to control the refractory metal based CMP process. Common oxidants suitable for use with the invention include hydrogen peroxide, potassium iodate, potassium ferricynide and perchlorate. The oxidant concentration is generally from 1 to 30 wt. %. A preferred oxidant concentration is from 2 to 5 wt. %.

The refractory metal polishing rate, such as the Ta polishing rate, generally decreases for relatively high oxidant concentrations. For example, high oxidant concentrations result in a low Ta removal rate because oxidants enhance the formation of tantalum oxide on the tantalum surface. Tantalum oxide is harder and more chemically passive compared to tantalum. Thus, the concentration of an oxidizing agent can be used to control the tantalum CMP process.

Complexing agents can also be added to the refractory metal based slurry to selectively increase the refractory based metal barrier layer removal rate. Preferred complexing agents can increase the refractory based metal barrier layer removal rate without altering the gate or interconnect metal layer or silicon dioxide removal rate. Examples of complexing agents include nitric acid, acetic acid, sulfuric acid, hydroxy acid, carboxylic acid, citric acid, malic acid, malonic acid, succinic acid, phtalic acid, tartaric acid, dihydroxysuccinic acid, lactic acid, malic acid, fumaric acid, adipic acid, maleic acid, glutaric acid, oxalic acid, benzoic acid, propionic acid, butyric acid and valeric acid.

Generally, comparatively weak complexing agents are preferably used. Preferred complexing agents include citric acid, acetic acid, tartaric acid and acetic acid. The concentration of the complexing agent can be from approximately 0.1 mM to 0.5 M. The preferred concentration of complexing agents is from 0.02 M to 0.2 M.

The slurry can also include salts. Salts, such as chlorides, nitrates and ammonium-based salts, may be added to further increase the stability of the selective adsorption additive. For example, KI, KBr, KCO₃, NH₄I, KCl, NH₄NO₃ and NH₄Cl may be used. However, non-alkali containing salts, such as NH₄Cl and NH₄NO₃ are generally preferred. The concentration of salt can be 0.1 mM to 0.5 M. A preferred concentration of salt is from 1 mM to 50 mM.

Polishing pressure can affect CMP removal rates for refractory metal based, copper, silver and silicon dioxide films. Polishing pad pressure is generally set to a pressure from 0.5 psi to 10 psi. Preferably, the polishing pressure range is 2.7 psi to 9 psi. Increasing polishing pressure can be used to increase the refractory metal based barrier layer removal rate, while not significantly affecting removal rates for the interconnect or gate level metal and underlying dielectric layer. For example, copper and silicon dioxide removal rates may remain constant as the polishing pressure is varied due to the formation of a Cu passivated layer such as Cu—BTA, and the selective adsorption of surfactant (e.g C₁₂TAB) on the silicon dioxide surface and the surface of the slurry particles. Thus, pressure can be used to optimize the removal rate of refractory metal based barrier layer films as well as improve the refractory metal based barrier layer selectivity to materials such as Cu and silicon dioxide.

Other additives may be included in the slurry. For example, in the case of a copper or silver interconnect or gate layer, the slurry can provide, either directly or indirectly, a reagent for reacting with the copper or silver film to form a soft layer on the surface of the copper or silver film. The soft layer has a hardness less than copper or silver oxide. For example, in conventional copper CMP, cuprite (Cu₂O) and/or copper II oxide (CuO) are formed on the copper surface. Cuprite or copper II oxide have a hardness, such as measured on the Mohs scale, which is greater than that of copper.

Chemical for forming soft layers on the copper or silver surface include iodine, bromine, fluorine, sulfuric acid, hydrochloric acid or carbonic acid or salts, such as KBr or KI. In the case of a copper film, the soft layer can be copper bromide, copper fluoride, copper chloride, copper carbonate, copper sulfate or copper nitrate or any these layers mixed with an oxide layer.

The invention can also be used as a single step polishing process for a metal/barrier layer/dielectric structure, such as Cu/Ta/SiO₂ or Ag/Ta/SiO₂. A single step process as used herein refers to a polishing which utilizes a single slurry mixture, the single slurry mixture including a chemical mixture along with a fixed concentration of composite particles.

The single step CMP process polishes a structure which includes a gate or interconnect metal film, a refractory metal based barrier film and a dielectric film. The single step process includes the steps of providing a slurry including a plurality of composite particles and at least one selective adsorption additive, the composite particles including an inorganic core surrounded by a shell including the selective adsorption additive. The gate or interconnect metal film can comprise copper or silver, and alloys thereof.

The refractory metal based barrier film and the gate or interconnect metal film do not substantially adsorb the selective adsorption additive, while the dielectric film does substantially adsorb the selective adsorption additive. The slurry is applied to the structure. Overburden regions of the gate or interconnect metal film are removed and then overburden regions of the refractory based barrier film are removed by the polishing pad in a single polishing step that can be continuous.

The selectivity of the gate or interconnect metal film to the dielectric film can be at least 100, the selectivity of the gate or interconnect metal film to the refractory based barrier film is at least 1 and the selectivity of the refractory based barrier film to the dielectric film is at least 100.

The selectivity of the gate or interconnect metal film to the dielectric film is preferably at least 100.

The inorganic cores are preferably multiphase particles, the multiphase particles comprising a first material coated with at least one other material. The surface of the inorganic core can be selected to be chemically equivalent to the dielectric layer.

The slurry for the single step process can include at least one passivating additive for inhibiting the oxidation of a copper or silver containing film, such as benzotriazole (BTA), tolytriazole (TTA), imidazole, thiols, mercaptans, oxalic acid, sodium hexanoate and carboxylic acid. The concentration of the passivating additive is preferably from 1 mM to 1 Mole.

Complexing agents can also be used, such as acetic acid, citric acid, tartaric acid and succinic acid. The pH of the slurry is preferably from 6 to 13.

The selective adsorption additive can be one or more non-ionic, anionic, cationic or zwitterionic surfactants. For example, the selective adsorption additive can be SAS, SDS, CTAB (e.g. C₁₂TAB), TRITON X-100® and TWEEN-80®, and KETJENLUBE 522®. The concentration of surfactant can be from 0.1 of a bulk CMC of the solution to 1000 of the CMC. In one embodiment, the selective adsorption additive comprises CTAB or CTAC, and the inorganic cores comprise silica.

The selective adsorption additive can be at least one polymer. For example, the polymer can be polyethylene oxide (PEO), polyacrylic acid (PAA), polyacryamide (PAM), polyvinylalcohol (PVA) or polyalkylamine (PAH).

The slurry can also include at least one salt, such as chlorides, nitrates and ammonium-based salts and at least one oxidizer, such as hydrogen peroxide, potassium ferrocyanide, potassium iodate, or a perchlorate. Preferred salts are non-alkali containing salts, such as NH₄Cl and NH₄NO₃

### EXAMPLES

### Example 1

### AFM Measurement to Demonstrate Surfactant Adsorption Selectivity

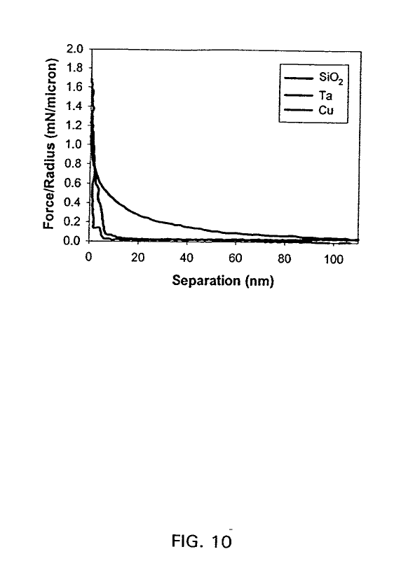

This Example shows the force between a silica particle and tantalum, copper and silicon dioxide films using atomic force microscopy (AFM). FIG. 10 shows force measurements on tantalum, copper and silicon dioxide substrates in a slurry solution including 20 mM Benzotriazole (BTA) and 16 mM dodecyltrimethylammonium bromide (C₁₂TAB) and silica particles, the solution having a pH of 9. CTAB and BTA can both function as surfactants. The results show that the separation distance (plotted on the x-axis) of the silica particles and the SiO₂ substrate surface is changed by adding BTA and C₁₂TAB. Specifically, the silica-silicon dioxide interaction shows higher force and long interaction distance than silica/Ta or silica/Cu. This result evidences the highly selective adsorption of surfactant on the silicon dioxide and silica particle surfaces.

The interaction forces between the AFM tip and a specific substrate, such as copper, silicon dioxide or Ta, were measured in a solution containing 20 mM BTA and 16 mM C₁₂TAB. In this measurement, a specific substrate is brought closer to the AFM tip and the interaction forces are measured by the deflection of the tip which has a specific spring constant. Thus, the force/radius of the tip can be plotted as a function of the separation distance. If the interaction force is repulsive, it is shown as a positive interaction force, whereas if the interaction force is attractive, it is shown as a negative interaction force.

Particles of different sizes can be attached to the AFM tip mimic the interaction of particles on the surface of the film during the CMP process. In these force measurements, silica particles were attached on the AFM tip. This diagram shows that the silica surface has the highest repulsion force under all separation distances, whereas tantalum has the lowest repulsive interaction barrier. Also, one can observe in Ta that the repulsive barrier due to desorption of the surfactant is broken (slope reversal) close to the surface. The barrier layer for copper lies in between the Ta and silica layers.

The high relative repulsive force between silica particles and the underlying silicon dioxide film indicates the formation of a soft shell structure on both the silica particles and the silicon dioxide film. The shell structure may be a single or a multiple layer, such as a micelle. The high repulsive force minimizes the CMP removal rate of silicon dioxide by isolating the silica particles from the silicon dioxide surface.

The surfactant adsorption on the copper film is measurable but weak as evidenced by the weak repulsive force shown in FIG. 10. This leads to some removal of copper during the tantalum polishing process, although the rate of polishing is reduced by the measurable surfactant adsorption on the copper surface.

The repulsive force shown is the lowest between the silica particles and the tantalum film. This is believed to be either due to little adsorption of selective adsorption additive on tantalum. Alternatively or additionally, the surfactant structure formed may have a low bond strength or elastic strength which may break up or disappears upon application of a load. Thus, since surfactant is not strongly or even generally measurably adsorbed by the tantalum layer, the abrasive silica particle can preferentially polish the tantalum layer.

### Example 2

### Surfactant Effect

In this example, the removal rates of tantalum, copper and silicon dioxide films were investigated by varying the surfactant concentration of surfactants such as SAS, CTAB, TRITON X-100® and TWEEN-80®, and KETJENLUBE 522®. It is noted that alkali metal based surfactants can be replaced with non-alkali based ions if alkali contamination concerns are present. The CMC values for specific surfactants are given below.

The removal rates of the three films using different surfactants and the resulting Ta/Cu/silicon dioxide selectivity values are shown in Table 1. The concentration of each surfactant was set at 1 CMC. The bulk CMC values for various surfactants varies significantly and can depend on factors such as the nature of the hydrophilic head and hydrophobic tails groups, presence of counter ions and co-ions and temperature. The CMC values for C₈TAB, C₁₀TAB, C₁₂TAB, and C₁₆TAB, C₁₄TAB and TRITON-X-100® are 144 mM, 66 mM, 15 mM, 0.9 mM, 0.23 mM, and 3.6 mM, respectively.

Other slurry components were 20 mM BTA, 5 wt. % silica particles having sizes around 0.5 μm. The slurry had a pH of 9. The pad pressure was 6.7 psi, while the linear velocity was 253 ft/min. The table below shows that the removal rates of silicon dioxide is decreased as the carbon chain length of CTAB is lengthened from 8 to 14. The chain length changes the length of the hydrophobic part of the surfactant and thus strengthens the micelle interaction.

TABLE 1
The removal rates of tantalum/copper/silicon dioxide using different surfactants

| | Surfactant | | | | | |
|---|---|---|---|---|---|---|
| | No additive | C₈TAB | C₁₂TAB | C₁₀TAB | C₁₄TAB | TRITON X-100 ® |
| Removal Rate | | | | | | |
| (nm/min) | | | | | | |
| Ta | 335.1 | 147.5 | 34.4 | 450 | 208.8 | 227.0 |
| Cu | 31.8 | 27.7 | 19.6 | 32.6 | 40.9 | 16.6 |
| Silicon | 392.1 | 0.1 | 0.2 | 0.1 | 0.1 | 341.2 |
| dioxide | | | | | | |
| Selectivity of Ta/SiO₂ | 0.85 | 1475 | 172 | 450 | 2088 | 0.67 |
| Selectivity of Cu/SiO₂ | 0.08 | 277 | 98 | 326 | 409 | 0.05 |
| Selectivity of Ta/Cu | 10.5 | 5.32 | 1.75 | 1.38 | 5.105 | 13.67 |

The above table shows that TRITON X-100® does not substantially increase the metal to dielectric selectivity. Thus, only specific surfactants in specific concentrations are generally helpful. The SAR values for CTAB having 8 to 14 carbons can be as high as 2500, strongly showing the selective adsorption effect.

### Example 3

### Surfactant Concentration Effect

As shown in Example 2, C₁₂TAB can produce selective adsorption on certain materials. In this example, the effect of varying the C₁₂TAB concentration was investigated. The concentration of C₁₂TAB was varied from 0 to 64 mM. The slurry included 5 wt. % silica particles having sizes of approximately 0.3 μm and 20 mM BTA. The pH was held at a constant value of 9. The pressure on the sample was 6.7 psi, while the linear velocity was 253 ft/min.

The resulting polish rates and selectivity of tantalum/copper/silicon dioxide are shown in Table 2 below. Table 2 demonstrates that the removal rates and selectivity of materials can be controlled by varying the surfactant concentration, the surfactant here being C₁₂TAB. At very low surfactant concentrations, the Ta/SiO₂ selectivity is low, such as <1. The selectivity of Ta/SiO₂ can be increased to 1500 or more when the surfactant concentration is optimized at a higher level as described below. The SAR_{Ta/Cu} can also be greater than 5 using the C₁₂TAB surfactant, while still providing a minimal silicon dioxide removal rate. Thus, by controlling the surfactant and its concentration, the AR, SAR and selectivity values can be accordingly modified.

When 1 mM of C₁₂TAB was added to the slurry, the SiO₂ polishing rate was still very high, being approximately 350 nm/minute, the Ta removal rate was 330 nm/min, while the Cu polishing rate was 26 nm/min. Under these conditions, the selectivity of Ta/SiO₂ was 0.89, the selectivity of Cu/SiO₂ was 0.07 and the selectivity of Ta/Cu was 12.70.

The data indicates that above a certain concentration of surfactant between (1 mM and 4 mM), the AR values of the dielectric, SAR values of Ta to SiO₂, and tantalum to SiO₂ selectivity increase by more than 3 orders of magnitude, from less than 1.0 to over 1000. This surfactant interaction can be defined as a Type I interaction. A Type I interaction shows substantial non-linear increase in AR values of the dielectric above a specific surfactant additive concentration, whereas for a Type II interaction, the adsorption increase is more linear in nature. Typically, a silicon dioxide surface shows a Type I interaction behavior whereas metals/refractory barriers show Type II adsorption behavior. After a rapid increase in the selectivity, with a further increase in surfactant concentration the selectivity starts to decrease due to a reduced polish rate of the metal. It should be noted that the planarity and surface defectivity such as dishing, erosion and dielectric loss, can also be controlled by appropriate selection of surfactant concentration provided to the slurry.

TABLE 2
Surfactant concentration effect

| | Concentration of C₁₂TAB | | | |
|---|---|---|---|---|
| | No C₁₂TAB | 4 mM | 16 mM | 64 mM |
| Removal Rate | | | | |
| (nm/min) | | | | |
| Ta | 335.1 | 335.3 | 174.9 | 9.2 |
| Cu | 31.8 | 4.4 | 9.0 | 9.0 |
| Silicon | 392.1 | 0.20 | 0.2 | 0.1 |
| dioxide | | | | |
| Selectivity of Ta/SiO₂ | 0.85 | 1676.5 | 875 | 92 |
| Selectivity of Cu/SiO₂ | 0.08 | 22 | 45 | 90 |
| Selectivity of Ta/Cu | 10.53 | 16.2 | 19.4 | 1.0 |

### Example 4

### Particle Size Effect

In this Example, silica particles in the slurry were provided in sizes ranging from 0.05 μm to 1 μm. The concentration of silica particles was 5% by weight. The slurry included 20 mM BTA and 16 mM C₁₂TAB. The pH was held at 9. The pad pressure was 6.7 psi and the linear velocity was 253 ft/min. Table 3 shows that the polishing rate of tantalum increased and then decreased quite substantially as the size of particles in the tantalum CMP slurry was increased, while holding the concentration of silica particles constant in the slurry.

The removal rates of copper and silicon dioxide did not significantly change as the particle size was varied. This is likely due to a chemically modified layer and surfactant layer, respectively. However, the surface defectivity of copper was found to increase with the increasing particle size. These results suggest that there is the optimal particle size to achieve a higher removal rate of tantalum and a high tantalum/copper/silicon dioxide selectivity.

TABLE 3
Effect of the particle size on tantalum CMP

Particle size (μm)

| | 0.2 | 0.3 | 0.5 | 1.0 |
|---|---|---|---|---|
| Removal Rate | | | | |
| (nm/min) | | | | |
| Ta | 20.8 | 174.9 | 34.4 | 13.0 |
| Cu | 28.2 | 9.0 | 19.6 | 12.0 |
| Silicon | 0.2 | 0.2 | 0.2 | 0.2 |
| dioxide | | | | |
| Selectivity of Ta/SiO₂ | 104 | 875 | 172 | 65 |
| Selectivity of Cu/SiO₂ | 14 | 45 | 98 | 48 |
| Selectivity of Ta/Cu | 0.74 | 19.5 | 1.76 | 1.2 |

### Example 5

### Particle Concentration Effect

In this example, the effect of particle concentration on tantalum CMP was considered. The slurry included 20 mM BTA and 16 mM C₁₂TAB, held at a pH of 9. The pad pressure was 6.7 psi and the linear velocity was 253 ft/min. Table 4 shows a higher removal rate of tantalum for increasing particle concentration. The selectivity to tantalum/copper/silicon dioxide was not changed significantly with varying particle concentration.

TABLE 4
Particle concentration effect on the tantalum CMP

Particle concentration

| | 5 wt. % | 10 wt. % |
|---|---|---|
| Removal Rate | | |
| (nm/min) | | |
| Ta | 174.9 | 229.1 |
| Cu | 9.0 | 11.9 |
| Silicon | 0.2 | 0.40 |
| dioxide | | |
| Selectivity of Ta/SiO₂ | 875 | 573 |
| Selectivity of Cu/SiO₂ | 45 | 30.0 |
| Selectivity of Ta/Cu | 19.4 | 19.3 |

### Example 6

### Effect of pH

Table 5 shows the effect on CMP for different pH values. The slurry used included 20 mM BTA, 16 mM C₁₂TAB and 5 wt. % silica particles having sizes of approximately 0.5 μm. The pressure on the samples was 6.7 psi, while the linear velocity was 253 ft/min. The pH was varied from 1 to 13. Table 5 shows that removal rates were increased as the pH was increased, and that the change in removal rates at different pHs were dependent upon the materials. The increased polishing rate for tantalum with increasing pH (up to a pH of 9) may result from chemical interactions with the silica particles.

TABLE 5
Effect of pH on the removal rates

PH

| | 4 | 7 | 9 | 11 |
|---|---|---|---|---|
| Removal Rate | | | | |
| (nm/min) | | | | |
| Ta | 8.4 | 9.6 | 34.4 | 23.3 |
| Cu | 36.2 | 37.2 | 19.6 | 41.7 |
| Silicon | | | 0.2 | 0.0 |
| dioxide | | | | |
| Selectivity of Ta/SiO₂ | 0.62 | 1.17 | 172 | 116.5 |
| Selectivity of Cu/SiO₂ | 2.70 | 4.53 | 98 | 208.5 |
| Selectivity of Ta/Cu | 0.23 | 0.260 | 1.76 | 0.560 |

### Example 7

### CMP Polishing Rate as a Function of Polishing Pressure

This Example shows the removal rate of tantalum/tantalum nitride, copper and silicon dioxide polishing as a function of polishing pressure. In this Example, the polishing pressure was varied from 0.5 psi to 10 psi. The CMP slurry included 20 mM BTA, 16 mM C₁₂TAB and 5 wt. % silica particles having sizes of approximately 0.5 μm. The pH of slurry was held constant at 9.

Table 6 shows that the removal rate of tantalum increases with pressure, whereas the removal rates of copper and silicon dioxide are essentially invariant to changes in polishing pressure. The pressure invariance of copper and silicon dioxide films may result from formation of a Cu-BTA layer and the selective adsorption of C₁₂TAB on silicon dioxide and abrasive particle surfaces. From these results, it can be concluded that the removal rate of tantalum/tantalum nitride and the selectivity of Ta/Cu/silicon dioxide can be optimized using polishing pressure.

TABLE 6
CMP polish rate as a function of pressure

Pad Pressure (psi)

| | 2.7 | 4.3 | 6.7 | 8.7 |
|---|---|---|---|---|
| Removal Rate | | | | |
| (nm/min) | | | | |
| Ta | 4.6 | 6.3 | 34.4 | 40.1 |
| Cu | 8.2 | 10.1 | 19.6 | 38.9 |
| Silicon | 0.2 | 0.2 | 0.2 | 0.2 |
| dioxide | | | | |
| Selectivity of Ta/SiO₂ | 23 | 31.5 | 172 | 200.5 |
| Selectivity of Cu/SiO₂ | 41 | 50.5 | 98 | 195.0 |
| Selectivity of Ta/Cu | 0.57 | 0.623 | 1.75 | 1.03 |

### Example 8

### Hydrogen Peroxide Concentration Effect

This Example shows the effect of varying the concentration of an oxidant on CMP removal rates for tantalum, copper and silicon dioxide. The concentration of hydrogen peroxide in a slurry containing 20 mM BTA, 16 MM C₁₂TAB and 5 wt. % silica particles having sizes of approximately 0.5 μm was varied from 0 to 10 wt. %. The experiments were conducted at 6.7 psi. The pH during polishing was maintained at 9.0. The linear velocity during the polishing process was approximately 253 ft/min.

Table 7 shows the results of tantalum CMP for different hydrogen peroxide concentrations. As shown, the Cu polishing rate is more sensitive to the hydrogen peroxide concentration, as compared to both SiO₂ and Ta. A 2% hydrogen peroxide concentration was found to provide high selectivity for both Ta/SiO₂ and Ta/Cu.

TABLE 7
The performance of the tantalum CMP as a function of the
concentration of hydrogen peroxide.

| | Concentration of H₂O₂ | | |
|---|---|---|---|
| | No H₂O₂ | 2 wt. % | 5 wt. % |
| Removal Rate | | | |
| (nm/min) | | | |
| Ta | 34.4 | 37.1 | 32.9 |
| Cu | 19.6 | 2.0 | 5.4 |
| Silicon | 0.2 | 0.2 | 0.1 |
| dioxide | | | |
| Selectivity of Ta/SiO₂ | 172 | 186 | 165.0 |
| Selectivity of Cu/SiO₂ | 98 | 10 | 56.0 |
| Selectivity of Ta/Cu | 1.76 | 18.6 | 6.1 |

### Example 9

### Effect of a Weak Complexing Agent

In this Example, citric acid was added to a slurry to enhance the CMP removal rates of tantalum. Table 8 shows the CMP polish rates of tantalum/copper/silicon dioxide layers with a slurry including 20 mM of BTA, 16 mM C₁₂TAB and 5 wt. % silica particles having sizes of approximately 0.5 μm. The concentration of citric acid was varied from 0 to 50 mM. The slurry pH was kept at 9. The pressure was 6.7 psi and the linear velocity was 253 ft/min.

The results show that the CMP polish rate of tantalum increased when the concentration of citric acid was increased. The data also shows that the removal rates of copper and silicon dioxide were not substantially changed even when high concentrations of citric acid (e.g. 50 mM) were added to the slurry.

TABLE 8
The effect of citric acid on the Ta CMP

| | Concentration of citric acid | | |
|---|---|---|---|
| | No citric acid | 10 mM | 50 mM |
| Removal Rate | | | |
| (nm/min) | | | |
| Ta | 34.4 | 41 | 127.2 |
| Cu | 19.6 | 12.9 | 18.9 |
| Silicon | 0.2 | 0.5 | 0.1 |
| dioxide | | | |
| Selectivity of Ta/SiO₂ | 172 | 205.0 | 1272 |
| Selectivity of Cu/SiO₂ | 98 | 65.0 | 189 |
| Selectivity of Ta/Cu | 1.76 | 3.20 | 6.73 |

### Example 10

### BTA Effect

In this Example, the removal rates of tantalum, copper and silicon dioxide films were investigated by varying the concentration of BTA in the slurry. The slurry included 16 mM C₁₂TAB and 5 wt. % silica particles having an average size of around 0.5 μm, the solution having a pH of 9. The concentration of BTA was varied from 0 to 50 mM. The pressure on the samples was 6.7 psi, while the linear velocity used was 253 ft/min.

Table 9 shows the effect of BTA on the polishing rate of tantalum, copper and silicon dioxide. The polishing rate of copper is seen to decrease gradually as the concentration of BTA is increased due to inhibiting copper oxide formation during CMP. On the other hand, the removal rate of tantalum and silicon dioxide are not apparently influenced by the addition of BTA to the slurry. In addition, less copper surface defects were observed when BTA was added to the slurry.

TABLE 9
Effect of BTA on the performance of the tantalum CMP slurry

| | Concentration of BTA | | | |
|---|---|---|---|---|
| | No inhibitor | BTA | | |
| | BTA | 1 mM | 5 mM | 20 mM |
| Removal Rate | | | | |
| (nm/min) | | | | |
| Ta | 65.5 | 31.2 | 8.4 | 34.4 |
| Cu | 46.6 | 53.8 | 23.5 | 19.6 |
| Silicon | 1.8 | 4.0 | 3.6 | 0.2 |
| dioxide | | | | |
| Selectivity of Ta/SiO₂ | 36.4 | 75 | 7.9 | 122 |
| Selectivity of Cu/SiO₂ | 25.9 | 12.8 | 6.5 | 98 |
| Selectivity of Ta/Cu | 1.4 | 0.58 | 1.21 | 1.76 |

### Example 11

### Dishing and Erosion Reduction from High Ta/Cu Selectivity

Good planarity can reduce the surface defectivity, such as dishing and erosion. One way to maintain good planarity is by limiting the thickness of tantalum oxide to less than 200 nm. In this Example, chemicals were added to the slurry to inhibit tantalum oxidation.

Both dishing and erosion defects are generally present on the incoming wafers for tantalum CMP because the slurry used for copper polishing generally has a higher polishing rate for copper as compared to tantalum. To reduce the dishing and erosion, the tantalum CMP slurry preferably has a higher tantalum polishing rate compared to copper.

Experiments were conducted with a 2 step polish on patterned wafers to determine the resulting dishing and erosion characteristics. In the first CMP step, copper was polished using an iodine based slurry including 0.01 N iodine, 20 mM BTA and 5 mM citric acid at a pH of 4. Dishing was measured to be between 50 and 150 nm for a 50 micron line and 50% density and erosion of less than 5 nm for a 2 micron line was observed after the copper polishing process.

After the copper polishing process, the tantalum/copper layer was polished using a slurry containing 20 mM BTA, and 15 mM C₁₂TAB, 0.01 to 0.1 M citric acid at a pH of 9.0. BTA can act as a corrosion inhibitor for both copper and the tantalum layers. The dishing and corrosion values were measured. The dishing was found to be 80 nm, while the erosion was less than 5 nm. No visible dielectric loss was observed in the process. Thus, the tantalum polishing process can reduce dishing and provide negligible erosion and dielectric loss.

### Example 12

### Use of Low K Dielectrics

The effect of surfactants and additives on AR, SAR and Selectivity values have been found to be similar if low dielectric constant materials, such as low K dielectric materials are used instead of SiO₂. This Examples shows that the adsorption ratio (AR), selective adsorption ratio (SAR), and selectivity of a low K silicon oxy-carbide material to surfactants and additives is similar to corresponding values for SiO₂. The oxy-carbide material has a dielectric constant of approximately 3.0. A slurry including 5 wt. % 0.3 μm silica particles and 20 mM BTA (PH of 9) used to polish the Ta and low K dielectric layers. 20 mM BTA represented approximately 1 CMC. The polish rate of the low K dielectric exceeded 500 nm/minute when no surfactant was used. However, the polishing rate dropped to less than 0.5 nm when 1 CMC C₁₂TAB was used. Thus, a change in metal to dielectric selectivity achieved was approximately 1000 with the addition of 1 CMC of the surfactant C₁₂TAB.

### Example 13

### Polishing of a TiN Barrier Metal

In this Example, TiN polishing was demonstrated. The slurry included 16 mM C₁₂TAB, 20 mM BTA, and 0.1 M citric acid. 5 wt. % silica particles were provided having an average size of around 0.5 μm. The slurry had a pH of 9. The pressure on the samples was 6.7 psi, while the linear velocity was 253 ft/min. A polishing rate of approximately 40 nm/min was measured for the TiN film.

### Example 14

### Single Step CMP Polish a Structure Including a Gate or Interconnect Metal, Refractory Metal Based Film and a Dielectric Film

Slurries was prepared with 3% by weight multiphase core particles formed from alumina particles (obtained from Nanophase Technologies Corporation, Romeoville, Ill.) which were coated with thin layers (<50 nm) of silica using the Stober process. In the slurry formulation, 20 mM C₁₂TAB, 20 mM BTA, 50 mM citric acid and 5% Hydrogen peroxide solutions were added. The pH was adjusted to 9.0. Polishing studies were conducted at 6.7 psi at 253 ft/min.

Under the above conditions, the polish rate for copper was 250 nm/per minute, the polish rate for tantalum was 150 nm per/minute and the polish rate for SiO₂ was <0.5 nm/minute. Thus, a selectivity of greater than 500 was obtained for Cu/SiO₂, a selectivity of greater than 300 was obtained for Ta/SiO₂ and a selectivity of approximately 1.7 for Cu/Ta. Thus, the invention can be used for polishing a structure having a gate or interconnect metal, such as copper or silver and a refractory metal based layer, such as Ta, in a single step.

The single step slurry can be used to polish a Cu/refractory metal/dielectric structure and provide a Cu/refractory metal selectivity of at least 1, and a Cu/dielectric selectivity of at least 50. More preferably, the Cu/dielectric selectivity is at least 100, and most preferably at least 500. The single step slurry and method can also provide a refractory metal/dielectric selectivity of at least 50, more preferably at least 100, 250 or more, or most preferably ast least 500.

It should be noted that good selectivity results can also be expected for multiphase silica coated quartz, silicon nitride or silicon carbide core particles, or other inner cores which are preferably harder than the SiO₂ or other dielectric provided by the structure for polishing. Given the high polish rates for copper, low polishing rate for the dielectric and an intermediate polishing rate for the refractory based metal layer (tantalum) demonstrated above, this slurry embodiment is particularly well suited for the single step slurry and method where a structure including a gate or interconnect metal and refractory metal based film can be polished in a single continuous polishing step with a single slurry composition. However, the above slurry can also be used to polish single layers, such as a refractory metal based barrier layer.

While the preferred embodiments of the invention have been illustrated and described, it will be clear that the invention is not so limited. Numerous modifications, changes, variations, substitutions and equivalents will occur to those skilled in the art without departing from the spirit and scope of the present invention as described in the claims.

We claim:

1. A slurry for chemical mechanical polishing (CMP) of a structure including a refractory metal based barrier film and a dielectric film, comprising:
a plurality of composite particles and at least one selective adsorption additive, said composite particles including an inorganic core surrounded by a shell including said selective adsorption additive, wherein said selective adsorption additive is substantially adsorbed by said dielectric film but not substantially adsorbed by said refractory metal based barrier film.

2. The slurry of claim 1, wherein said inorganic cores comprise at least one selected from the group consisting of silica, zirconia, yttria, titania, silicon nitride, silicon carbide and alumina.

3. The slurry of claim 1, wherein said inorganic cores are multiphase particles, said multiphase particles comprising a first material coated with at least one other material.

4. The slurry of claim 1, wherein a surface of said inorganic cores is selected to be chemically equivalent to said dielectric layer.

5. The slurry of claim 3, wherein said other material is selected to be chemically equivalent to said dielectric layer.

6. The slurry of claim 3, wherein said inorganic cores are at least one selected from the group consisting of silica, doped silica and nanoporous silica.

7. The slurry of claim 3, wherein said other material comprises at least one selected from the group consisting of silica, nanoporous silica and doped silica.

8. The slurry of claim 3, wherein said inorganic cores are at least one selected from the group consisting of alumina, zirconia, silicon nitride and said other layer is at least one selected from the group consisting of silica, doped silica and nanoporous silica.

9. The slurry of claim 1, wherein said selective adsorption additive exhibits substantial adsorption to said dielectric layer, said dielectric film selected from the group consisting of silicon dioxide, silicon nitride and low K materials.

10. The slurry of claim 1, wherein said selective adsorption additive exhibits adsorption to a copper or silver containing film greater than adsorption to said refractory metal based barrier film.

11. The slurry of claim 1, wherein a selectivity of a CMP process using said slurry is at least approximately 20 for said refractory metal based barrier film compared to said dielectric film, said dielectric film comprising a silicon dioxide or low K film.

12. The slurry of claim 1, wherein a selectivity of a CMP process using said slurry is at least approximately 100 for said refractory metal based barrier film compared to said dielectric film, said dielectric film comprising a silicon dioxide or low K film.

13. The slurry of claim 1, wherein a selectivity of a CMP process using said slurry is at least 0.5 for said refractory metal based barrier film compared to a layer comprising copper or silver.

14. The slurry of claim 1, wherein a selectivity of a CMP process using said slurry is at least 2.0 for said refractory metal based barrier film compared to a layer comprising copper or silver.

15. The slurry of claim 1, wherein a selectivity of a CMP process using said slurry is at least approximately 100 for a layer comprising copper or silver compared to said dielectric film, said dielectric film comprising a silicon dioxide or low K film.

16. The slurry of claim 1, wherein a selectivity of a CMP process using said slurry is at least approximately 11000 for a film comprising copper or silver compared to said dielectric film, said dielectric film comprising a silicon dioxide or low K film.

17. The slurry of claim 1, further comprising at least one organic solvent.

18. The slurry of claim 1, further comprising at least one passivating additive for inhibiting the oxidation of a copper or silver containing film.

19. The slurry of claim 18, wherein said passivating additive comprises at least one selected from the group consisting of benzotriazole (BTA), tolytriazole (TTA), imidazole, thiols, mercaptans, oxalic acid, sodium hexanoate and carboxylic acid.

20. The slurry of claim 1, further comprising at least one complexing agent.

21. The slurry of claim 20, wherein said complexing agent comprises at least one selected from the group consisting of acetic acid, citric acid, tartaric acid and succinic acid.

22. The slurry of claim 1, wherein said selective adsorption additive comprises at least one surfactant selected from the group consisting of non-ionic, an ionic, cationic and zwitterionic surfactants.

23. The slurry of claim 1, wherein said selective adsorption additive comprises at least one surfactant selected from the group consisting of SAS, SDS, CTAB, CTAC, TRITON X-100®, TWEEN-80®, AND KETJENLUBE 522®.

24. The slurry of claim 1, wherein said selective adsorption additive comprises CTAB or CTAC, and said inorganic cores comprise silica.

25. The slurry of claim 24, wherein said CTAB comprises C₁₂TAB.

26. The slurry of claim 25, wherein said oxidizer is at least one selected from the group consisting of hydrogen peroxide, potassium ferrocyanide, potassium iodate, and perchlorates.

27. The slurry of claim 22, wherein a concentration of said surfactant is from 0.1 of a bulk CMC of said solution to 1000 said CMC.

28. The slurry of claim 22, wherein a concentration of said surfactant is from 0.5 of said CMC to 100 times of said CMC.

29. The slurry of claim 1, wherein said selective adsorption additive comprises at least one polymer.

30. The slurry of claim 29, wherein said polymer is at least one selected from the group consisting of polyethylene oxide (PEO), polyacrylic acid (PAA), polyacryamide (PAM), polyvinylalcohol (PVA) and polyalkylamine (PAH).

31. The slurry of claim 1, further comprising at least one salt.

32. The slurry of claim 31, wherein said salt is at least one selected from the group consisting of chlorides, nitrates and ammonium-based salts.

33. The slurry of claim 1, wherein a pH of said slurry is from 6 to 13.

34. The slurry of claim 1, wherein a pH of said slurry is from 8 to 11.

35. The slurry of claim 1, wherein a concentration of said core particles in said slurry is from approximately 1% to 40% by weight.

36. The slurry of claim 1, further comprising at least one oxidizer.

37. The slurry of claim 36, wherein said oxidizer is at least one selected from the group consisting of hydrogen peroxide, pottasium ferrocyanide, pottasium iodate and perchlorates.

38. The slurry of claim 1, wherein said slurry provides adsorption ratio (AR) for a film comprising copper or silver of no more than 5, said refractory metal based barrier film of no more than 5, and said dielectric film of at least 10.

39. The slurry of claim 38, wherein an AR of said dielectric film is at least 1100.

40. The slurry of claim 38, wherein an AR of said dielectric film is at least 500.

41. The slurry of claim 1, wherein said slurry provides an adsorption ratio (AR) for a film comprising copper or silver of no more than 2, said refractory metal based barrier film of no more than 2, and said dielectric film of at least 10.

42. The slurry of claim 41, wherein an AR of said dielectric film is at least 100.

43. The slurry of claim 41, wherein an AR of said dielectric film is at least 500.

44. The slurry of claim 1, wherein said slurry provides a selective adsorption ratio (SAR) for a film comprising copper or silver to said refractory metal based barrier film of at least one.

45. The slurry of claim 1, wherein said slurry provides a SAR of said dielectric film to said refractory metal based barrier film of at least 50.

46. The slurry of claim 1, wherein said slurry provides a SAR of said dielectric layer to said refractory metal based barrier film of at least 100.

47. A slurry for chemical mechanical polishing (CMP) of a structure including a refractory metal based barrier film and a dielectric film, wherein said slurry provides a selectivity for a CMP process of at least approximately 50 for said refractory metal based barrier film compared to said dielectric film, said dielectric film comprising a silicon dioxide or low K film.

48. A slurry for chemical mechanical polishing (CMP) of a structure including a refractory metal based barrier film, copper film and a dielectric film, wherein said slurry provides a selectivity for a CMP process of at least approximately 100 for said copper film compared to said dielectric film, said dielectric film comprising a silicon dioxide or low K film.

49. A method for chemical mechanical polishing (CMP) a structure which includes a refractory metal based barrier film and a dielectric film, comprising the steps of:
providing a slurry including a plurality of composite particles and at least one selective adsorption additive, said composite particles including an inorganic core surrounded by a shell including said selective adsorption additive, wherein said selective adsorption additive is substantially adsorbed by said dielectric film but not substantially adsorbed by said refractory metal based barrier film,
applying said slurry to said structure, and
removing said refractory metal based barrier film using a polishing pad.

50. A method for chemical mechanical polishing (CMP) a structure which includes a refractory metal based barrier film and a dielectric film, comprising the steps of:
providing a slurry including a plurality of composite particles and at least one selective adsorption additive, said composite particles including an inorganic core surrounded by a shell including said selective adsorption additive, wherein said selective adsorption additive is substantially adsorbed by said dielectric film but not substantially adsorbed by said refractory metal based barrier film,
applying said slurry to said structure, and
removing said refractory metal based barrier film using a polishing pad, wherein said method provides a selectivity of at least approximately 50 for said refractory metal based barrier film compared to said dielectric film, said dielectric film comprising a silicon dioxide or low K film.

51. A single step chemical mechanical polishing (CMP) process for polishing a structure which includes a gate or interconnect metal film, a refractory metal based barrier film and a dielectric film, comprising the steps of:
providing a slurry including a plurality of composite particles and at least one selective adsorption additive, said composite particles including an inorganic core surrounded by a shell including said selective adsorption additive, said refractory metal based barrier film and said gate or interconnect metal film not substantially adsorbing said selective adsorption additive, said dielectric film substantially adsorbing said selective adsorption additive;
applying said slurry to said structure, and
removing overburden regions of said gate or interconnect metal film and then removing overburden regions of said refractory based barrier film using a polishing pad in a single polishing step.

52. The method of claim 51, wherein a selectivity of said gate or interconnect metal film to said dielectric film is at least 100, a selectivity of said gate or interconnect metal film to said refractory based barrier film is at least 1 and a selectivity of said refractory based barrier film to said dielectric film is at least 100.

53. The method of claim 51, wherein a selectivity of said gate or interconnect metal film to said dielectric film is at least 100.

54. The method of claim 51, wherein said gate or interconnect metal film comprises copper or silver, and alloys thereof.

55. The method of claim 51, wherein said inorganic cores are multiphase particles, said multiphase particles comprising a first material coated with at least one other material.

56. The method of claim 51, wherein a surface of said inorganic cores is selected to be chemically equivalent to said dielectric film.

57. The method of claim 51, wherein said slurry comprises at least one passivating additive for inhibiting the oxidation of a copper or silver containing film.

58. The method of claim 57, wherein said passivating additive comprises at least one selected from the group consisting of benzotriazole (BTA), tolytriazole (TTA), imidazole, thiols, mercaptans, oxalic acid, sodium hexanoate and carboxylic acid.

59. The method of claim 58, wherein a concentration of said passivating additive is from 1 mM to 1 Mole.

60. The method of claim 51, wherein said slurry comprises at least one complexing agent.

61. The method of claim 60, wherein said complexing agent comprises at least one selected from the group consisting of acetic acid, citric acid, tartaric acid and succinic acid.

62. The method of claim 51, wherein said selective adsorption additive comprises at least one surfactant selected from the group consisting of non-ionic, anionic, cationic and zwitterionic surfactants.

63. The method of claim 51, wherein said selective adsorption additive comprises at least one surfactant selected from the group consisting of SAS, SDS, CTAB, TRITON X-100® and TWEEN-80®, and KETJENLUBE 522®.

64. The method of claim 51, wherein said slurry comprises a salt, said salt being at least one selected from the group consisting of NH₄Cl and NH₄NO₃, NaCl and KCl.

65. The method of claim 62, wherein a concentration of said surfactant is from 0.1 of a bulk CMC of said solution to 1000 of said CMC.

66. The method of claim 51, wherein said selective adsorption additive comprises at least one polymer.

67. The method of claim 51, wherein said slurry includes at least one organic solvent.

68. The method of claim 51, wherein said slurry comprises at least one salt.

69. The method of claim 51, wherein a pH of said slurry is from 6 to 13.

70. The method of claim 51, wherein said slurry comprises at least one oxidizer.

71. The method of claim 70, wherein said oxidizer is at least one selected from the group consisting of hydrogen peroxide, potassium ferrocyanide, potassium iodate, and perchlorates.
